(19) United States
(12) Patent Application Publication
(10) Pub. No.: US 2012/0187551 A1
(43) Pub. Date: Jul. 26, 2012

(54) SEMICONDUCTOR MODULE

(76) Inventors: Masahiko KUSHINO, Osaka (JP); Masahiro MURAKAMI, Osaka (JP); Yoshihisa AMANO, Osaka (JP); Shinichi TOKUNO, Osaka (JP)

(21) Appl. No.: 13/323,495

(22) Filed: Dec. 12, 2011

(30) Foreign Application Priority Data
Jan. 20, 2011 (JP) 2011-009957

(51) Int. Cl. H01L 23/552

(52) U.S. Cl. 257/659; 257/E23.114

(57) ABSTRACT

Provided is a semiconductor module (A), including: a substrate (1) having an electronic component (2) mounted on an upper surface thereof; an encapsulation resin layer (3) having an insulating property, for encapsulating the upper surface; an exterior shielding member (4) having conductivity, for covering a side of the encapsulation resin layer (3) opposite to the substrate (1); and a connection portion (5), which is provided inside the encapsulation resin layer (3), for electrically connecting the exterior shielding member (4) and a ground terminal (13) provided to the substrate (1).

This application is based upon and claims the benefit of priority from the corresponding Japanese Patent Application No. 2011-9957 filed on Jan. 12, 2011, the entire contents of which are incorporated herein by reference.

### BACKGROUND OF THE INVENTION

1. Field of the Invention

The present invention relates to a resin-encapsulated semiconductor module.

2. Description of Related Art

Conventionally, in a semiconductor module to be used in electronic devices such as a mobile phone, a high-frequency circuit including a high-frequency semiconductor device and a peripheral circuit has been formed. Therefore, shielding against high frequency noise and the like is necessary, and hence the entire semiconductor module is covered with a metal shielding case. Further, in recent years, there has been an increasing demand for reduction in size of the electronic devices, and accordingly, there has also been an increasing demand for reduction in size and height of the semiconductor module.

However, in the case of the conventional semiconductor module, it is required to provide a pad (land) for attaching the metal shielding case to a module substrate, which prevents the reduction in size and height of the module.

In view of this, there is proposed an advanced semiconductor module in which the metal shielding case is omitted (with a metal-shielding-case-less structure). In the following, the advanced semiconductor module is described with reference to the drawings. FIG. 25 is a schematic sectional view of a conventional semiconductor module in an advanced form, and FIGS. 26 to 30 are schematic sectional views illustrating steps of manufacturing the semiconductor module illustrated in FIG. 25.

As illustrated in FIG. 25, an advanced semiconductor module G includes a module substrate 91, electronic components 92, such as a semiconductor device, a capacitor, and a resistor, which are mounted on an upper surface (component mounting surface) of the module substrate 91, an encapsulation resin layer 93, which is made of, for example, an epoxy resin, for encapsulating the electronic components 92, and an exterior shielding member 94 formed on the surface of the encapsulation resin layer 93.

On the component mounting surface of the module substrate 91, a signal conductor 911 is formed. The electronic component 92 is connected to the signal conductor 911 via a bonding wire Bw, or a terminal of the electronic component 92 is directly connected to the signal conductor 911. A ground line 913 is formed inside the module substrate 91, and the ground line 913 has an exposed part at an undersurface. The exterior shielding member 94 is made of a conductive material, and is formed so as to cover the upper surface and the side surface of the encapsulation resin layer 93. Further, the exterior shielding member 94 is provided in contact with the ground line 913 at a portion of the side surface thereof opposed to the module substrate 91. The exterior shielding member 94 is grounded by being provided in contact with the ground line 913. With this, it is possible to perform shielding against undesirable effects due to the electromagnetical field or static electricity (such as high frequency noise).

Steps of manufacturing the advanced semiconductor module are as follows. First, there is performed a mounting step of mounting the electronic components 92 on the upper surface of a collective substrate 910, which is to be cut to obtain the module substrates 91 (see FIG. 26). Then, by a conventionally well-known method such as a printing method, there is performed an encapsulating step of forming the encapsulation resin layer 93 for encapsulating the upper surface of the collective substrate 910, the encapsulation resin layer 93 being made of an insulating resin such as an epoxy resin (see FIG. 27). At this time, the collective substrate 910 has a structure in which a plurality of module regions (which become, after cutting and separation, the module substrates 91) are arranged.

Then, there is performed a first dicing step of forming slits in the encapsulation resin layer 93 from the upper surface side thereof using a dicing blade, the slits being formed at boundary portions of adjacent modules. In the first dicing step, the slits are formed in the encapsulation resin layer 93, and simultaneously, parts of the collective substrate 910 are removed to expose the ground line 913 formed inside the collective substrate 910 on the upper surface side (see FIG. 28).

By using a conventionally well-known method such as a printing method, conductive paste is filled in the slits formed in the encapsulation resin layer 93 (filling step). At this time, the conductive paste filled in the slits is brought into contact with the ground line 913 inside the collective substrate 910. Further, the conductive paste is coated onto the upper surface of the encapsulation resin layer 93 having the slits filled with the conductive paste (coating step, see FIG. 29). As illustrated in FIG. 29, by performing the filling step and the coating step so that the conductive paste is brought into contact with the ground line 913, the conductive paste is grounded. Note that, the layer of the conductive paste serves as the exterior shielding member 94 of the semiconductor module G.

Then, there is performed a second dicing step of cutting the collective substrate 910 at boundary portions of the adjacent modules, that is, center portions of the slits filled with the conductive paste, by using a dicing blade which is thinner than the width of the slit (thinner than the dicing blade used in the first dicing step) (see FIG. 30). As described above, by using, in the second dicing step, a dicing blade which is thinner than the dicing blade used in the first dicing step, after the second dicing step, the exterior shielding member 94 is formed on the side surface of the completed semiconductor module G (see FIG. 25). In this manner, the exterior shielding member 94 can be reliably grounded (see Japanese Patent Application Laid-open Nos. 2005-109306 and 2004-172176).

FIG. 31 is a plan view illustrating the collective substrate before the semiconductor modules are cut out in the second dicing step. By cutting the collective substrate 910, in which the modules are two-dimensionally arranged, with the dicing blade (second dicing step), a plurality of semiconductor modules G are manufactured.

FIG. 32 is a schematic sectional view illustrating a state in which the semiconductor module of FIG. 25 is mounted on a mounting substrate. As illustrated in FIG. 32, a module mounting terminal 912, which is formed on the undersurface of the module substrate 91, and a signal terminal St, which is formed on a mounting substrate Mb, are brought into contact with each other. The exterior shielding member 94 is formed so as to cover a part of the side portion of the module substrate 91, and hence it is possible to form the height smaller as compared to the conventional structure in which a case is attached to a pad (land) formed on the upper surface of the module substrate 91.

However, when the semiconductor module G is mounted on the mounting substrate Mb as illustrated in FIG. 32, depending on the amount of solder or a conductive resin adhesive used when the module mounting terminal 912 formed on the undersurface of the module substrate 91 and the signal terminal St of the mounting substrate Mb are connected to each other, there is a case where the signal terminal St of the mounting substrate Mb and the exterior shielding member 94 are short-circuited, which deteriorates workability.

Further, in a case where the semiconductor module is manufactured in the above-mentioned method, two dicing steps corresponding to the first dicing step and the second dicing step are necessary, and it is necessary to use dicing blades having different thicknesses in the respective dicing steps, which makes the manufacturing steps complicated. Further, a large amount of resin or conductive paste is removed by dicing. For the above-mentioned reasons, the productivity is liable to reduce, which leads to cost increase.

### SUMMARY OF THE INVENTION

The present invention has been made in view of the above-mentioned points, and has an object to provide a semiconductor module, which is capable of reliably grounding an exterior shielding member and further preventing a short-circuit between the exterior shielding member and signal wiring.

According to an aspect of the present invention, there is provided a semiconductor module, including: a substrate having an electronic component mounted on an upper surface thereof; an encapsulation resin layer having an insulating property, for encapsulating the upper surface on which the electronic component is mounted; an exterior shielding member having conductivity, for covering a side of the encapsulation resin layer opposite to the substrate; and a connection portion, which is provided inside the encapsulation resin layer, for electrically connecting the exterior shielding member and a ground terminal provided to the substrate.

With this structure, the connection portion connecting the exterior shielding member and the ground terminal is provided inside the encapsulation resin. Therefore, the exterior shielding member and the ground terminal can be reliably connected electrically, and it is possible to efficiently perform shielding against undesirable effects due to the electromagnetical field or static electricity (such as high frequency noise). Further, even if too much solder is provided in soldering, the connection portion can suppress occurrence of such a trouble that the signal wiring of the semiconductor module and the exterior shielding member are short-circuited. Therefore, there is a certain degree of adjustment margin in the solder amount when the semiconductor module is mounted on the mounting substrate. In this manner, productivity in assembling can be enhanced. Further, a cover to be attached above the substrate is unnecessary, and hence reduction in height and size is possible.

In a preferred embodiment of the present invention, the semiconductor module further includes a recessed portion formed therein, the recessed portion passing through the exterior shielding member and reaching at least an inner portion of the encapsulation resin layer, and the connection portion includes an inner peripheral portion, which covers an inner peripheral surface of the recessed portion and a contact portion provided in contact with the ground terminal.

In another preferred embodiment of the present invention, the substrate may have the ground terminal arranged on an undersurface thereof, and the recessed portion may pass through the encapsulation resin layer, the substrate, and the ground terminal. With this structure, the recessed portion may be used as a positioning hole when the module substrate is mounted onto the mounting substrate, and hence workability can be enhanced.

In a further preferred embodiment of the present invention, the recessed portion may pass through the encapsulation resin layer, and the contact portion of the connection portion may be formed so as to cover a bottom surface of the recessed portion so that the contact portion is provided in contact with the ground terminal formed on the upper surface of the substrate.

In a still further preferred embodiment of the present invention, the recessed portion may be formed above the electronic component, and the contact portion may be provided in contact with a conductor portion of the electronic component, which is connected to the ground terminal. At this time, the electronic component may be a semiconductor device including a through silicon via.

In a yet further preferred embodiment of the present invention, the ground terminal may be formed on the upper surface of the substrate, the substrate may have a conductive member mounted thereon, the conductive member being connected to the ground terminal and provided upright in a thickness direction of the substrate, and the contact portion may be provided in contact with the conductive member. As the conductive member provided upright, there may be exemplified a low resistance element, a jumper wire, and the like. There may be adopted various members, which may be easily provided upright.

In a yet further preferred embodiment of the present invention, the exterior shielding member is formed smaller in planar shape than the substrate. With this structure, it is possible to prevent the dicing blade, which is used when the module substrates are cut out and separated, from cutting the exterior shielding member, which is hard to cut compared with other portions. With this, wearing of the dicing blade is suppressed, and further, the stress or strain generated when the exterior shielding member is cut can be suppressed.

In a yet further preferred embodiment of the present invention, the semiconductor module may include a plurality of connection portions. In this case, there may be exemplified connection portions arranged so as to form a pair at least at diagonal positions of the substrate.

### BRIEF DESCRIPTION OF THE DRAWINGS

FIG. 1 is a schematic perspective view of an example of a semiconductor module according to the present invention.

FIG. 2 is a sectional view taken in the direction of the arrows along the line II-II of the semiconductor module illustrated in FIG. 1.

FIG. 3 is a sectional view of the semiconductor module illustrated in FIG. 2 and a mounting substrate in a state in which the semiconductor module is mounted.

FIG. 4 is a plan view of a state in which electronic components are mounted on a collective substrate.

FIG. 5 is a sectional view of the collective substrate illustrated in FIG. 4.

FIG. 6 is a sectional view illustrating the collective substrate after an encapsulating step.

FIG. 7 is a sectional view schematically illustrating a perforating step.

FIG. 8 is a plan view illustrating the collective substrate after the perforating step.

FIG. 9 is a sectional view of the collective substrate in a state in which a metal coating film is formed in a film forming step.

FIG. 10 is an enlarged sectional view of a through hole portion of FIG. 9.

FIG. 11 is a sectional view illustrating a dicing step.

FIG. 12 is a schematic sectional view of another example of the semiconductor module according to the present invention.

FIG. 13 is a sectional view of the semiconductor module illustrated in FIG. 12 and a mounting substrate in a state in which the semiconductor module is mounted.

FIG. 14 is a sectional view schematically illustrating a collective substrate during a drilling step.

FIG. 15 is a sectional view illustrating a state in which an encapsulation resin layer, which encapsulates the upper surface of the collective substrate, is irradiated with a laser beam.

FIG. 16 is a sectional view of the collective substrate after a film forming step.

FIG. 17 is an enlarged sectional view of a recessed hole portion of the collective substrate illustrated in FIG. 16.

FIG. 18 is a sectional view illustrating a dicing step.

FIG. 19 is an enlarged sectional view of still another example of the semiconductor module according to the present invention.

FIG. 20 is an enlarged sectional view of a modification example of the semiconductor module of FIG. 19.

FIG. 21 is an enlarged sectional view of further another example of the semiconductor module according to the present invention.

FIG. 22 is an enlarged sectional view of yet another example of the semiconductor module according to the present invention.

FIG. 23 is a plan view of yet another example of the semiconductor module according to the present invention.

FIG. 24 is a plan view illustrating a collective substrate after a film forming step of the semiconductor module illustrated in FIG. 23 is finished.

FIG. 25 is a schematic sectional view of a conventional semiconductor module in an advanced form.

FIG. 26 is a schematic sectional view illustrating a mounting step in manufacturing of the conventional semiconductor module.

FIG. 27 is a schematic sectional view illustrating an encapsulating step in the manufacturing of the conventional semiconductor module.

FIG. 28 is a schematic sectional view illustrating a first dicing step in the manufacturing of the conventional semiconductor module.

FIG. 29 is a schematic sectional view illustrating a filling step in the manufacturing of the conventional semiconductor module.

FIG. 30 is a schematic sectional view illustrating a second dicing step in the manufacturing of the conventional semiconductor module.

FIG. 31 is a schematic plan view illustrating a conventional collective substrate.

FIG. 32 is a sectional view of the semiconductor module illustrated in FIG. 25 and a mounting substrate in a state in which the semiconductor module is mounted.

### DETAILED DESCRIPTION OF PREFERRED EMBODIMENTS

Hereinafter, embodiments of the present invention are described with reference to the drawings. Note that, for the sake of convenience, the reference symbols and (or) hatching of the members are omitted in some cases, but in those cases, other drawings shall be referred to.

### First Embodiment

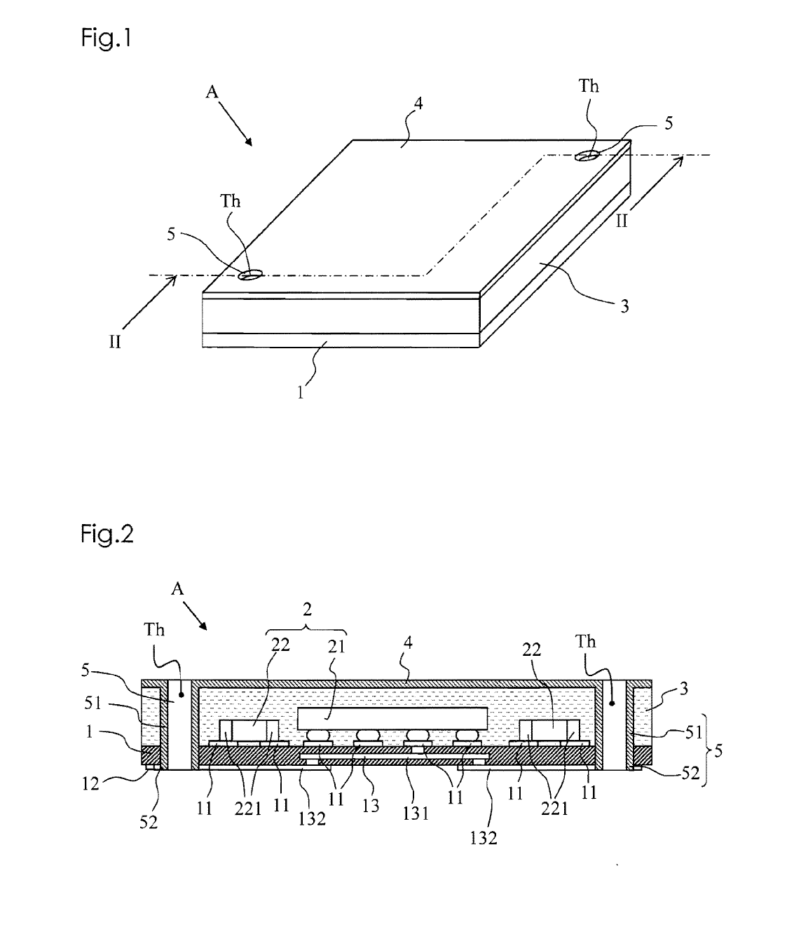

FIG. 1 is a schematic perspective view of an example of a semiconductor module according to the present invention, and FIG. 2 is a sectional view taken in the direction of the arrows along the line II-II of the semiconductor module illustrated in FIG. 1. First, referring to FIGS. 1 and 2, a structure of a semiconductor module A according to the present invention is described.

As illustrated in FIGS. 1 and 2, the semiconductor module A according to the present invention includes: a module substrate 1; a plurality of electronic components 2 mounted on an upper surface (corresponding to a main surface, and hereinafter, also referred to as a component mounting surface in some cases) of the module substrate 1; an encapsulation resin layer 3 for encapsulating the upper surface of the module substrate 1 including those electronic components 2; an exterior shielding member 4, which covers the upper surface of the encapsulation resin layer 3; and connection portions 5 formed integrally with the exterior shielding member 4. The module substrate 1 is an example of a “substrate” of the present invention, and is a substrate obtained by cutting a collective substrate 100 described below. Note that, in actual manufacturing steps, the collective substrate 100 is cut after the mounting and forming of the electronic components 2, the encapsulation resin layer 3, the exterior shielding member 4, the connection portions 5, and the like are finished.

Further, as illustrated in FIG. 1, the semiconductor module A has a square shape when viewed in plan (in plan view). The semiconductor module A has two through holes Th formed at diagonal positions of the square shape in plan view. The through hole Th is described in detail later, but when the semiconductor module A is mounted on a mounting substrate Mb, the through hole Th is used as a reference hole for positioning the semiconductor module A with respect to the mounting substrate Mb.

The module substrate 1 is a ceramic multilayer substrate having a predetermined thickness, and has a square shape in plan view. On the upper surface of the module substrate 1, there are formed wiring conductors 11, which are formed to have predetermined wiring patterns and are electrically connected to the electronic components 2, respectively. Further, on the undersurface of the module substrate 1, there is formed a module mounting terminal 12, which is electrically connected to the wiring conductor via a via-hole (not shown). Still further, in the inner layer and on the undersurface of the module substrate 1, a ground line 13 is formed. A part of the ground line 13 arranged in the inner layer (inner layer ground wiring 131) and a part of the ground line 13 formed on the undersurface (undersurface ground terminal 132) are electrically connected to each other. Note that, the wiring conductor 11, the module mounting terminal 12, and the ground line 13 are each formed of a low-resistance metal thin film, for example, a copper thin film.

Further, some of the wiring conductors 11 are connected to grounding conductors of the electronic components 2, and the wiring conductors 11 connected to the grounding conductors of the electronic components 2 are connected to the ground line 13 via via-holes (not shown) and the like. Note that, the inner layer ground wiring 131 of the ground line 13 is preferred to be formed in as wide an area of the arranged layer as possible. By forming the ground wiring 131 large as described above, it is possible to obtain an effect of shielding against undesirable effects from the undersurface side of the module substrate 1 due to the electromagnetical field or static electricity (such as high frequency noise).

The plurality of electronic components 2 mounted on the upper surface of the module substrate 1 include, as illustrated in FIG. 2, a semiconductor device 21 and passive components 22 such as a resistor, an inductor, and a capacitor. The plurality of electronic components 2 are arbitrarily selected to obtain intended functions, and are mounted on the component mounting surface of the module substrate 1. For example, when the semiconductor module A is used as a module for wireless transmission and reception of a mobile phone, a radio frequency integrated circuit (RF-IC) or the like is used as the semiconductor device 21.

The passive component 22 is a chip-type electronic component (chip component). The passive component 22 includes, for example, a sintered ceramic element body and external terminal electrodes 221 formed on both end portions of the element body.

The above-mentioned plurality of electronic components 2 are mounted at predetermined positions of the upper surface of the module substrate 1, and thereby connected to one another via the wiring conductors 11 (see FIG. 2) and the like of the module substrate 1 or alternatively grounded. In this manner, the semiconductor module A constitutes an integrated circuit. Note that, in the semiconductor module A, the semiconductor device 21 mounted on the upper surface of the module substrate 1 is an IC of a wafer level chip size package (WL-CSP) type. Further, on the module substrate 1, components such as a band pass filter (BPF) and a crystal oscillator are mounted as necessary.

Further, as described above, the upper surface of the module substrate 1, on which the electronic components 2 are mounted, is covered with the encapsulation resin layer 3, the electronic components 2 also being covered therewith. The encapsulation resin layer 3 encapsulates the electronic components 2 to serve as an insulating layer, and is formed so as to cover the entire upper surface of the module substrate 1. By forming the encapsulation resin layer 3, the electronic components 2 and the wiring conductors 11 are protected from stress, moisture, and contaminated materials from the outside. The encapsulation resin layer 3 is made of an insulating resin, for example, an epoxy resin. Note that, the material of the encapsulation resin layer 3 is not limited thereto, and materials such as a resin may be widely adopted, which are capable of encapsulating the upper surface of the module substrate 1 and the electronic components 2.

In the semiconductor module A, the through holes Th are formed, which pass through the module substrate 1, the encapsulation resin layer 3, and the undersurface ground terminal 132 of the ground line 13. That is, the through holes Th each have a shape passing from the upper surface to the undersurface of the semiconductor module A. Note that, the through holes Th pass through the undersurface ground terminal 132 of the ground line 13, and hence the undersurface ground terminal 132 is formed at areas of diagonal positions of the module substrate 1, at which the through holes Th are to be formed.

Further, the exterior shielding member 4 is formed so as to cover the upper surface of the encapsulation resin layer 3. The exterior shielding member 4 is formed of a metallic film having conductivity, for example, a copper film. In the semiconductor module A, the exterior shielding member 4 covers the entire upper surface of the encapsulation resin layer 3, and is firmly adhered to the upper surface of the encapsulation resin layer 3. Further, the connection portions 5 are formed, which is provided inside the through holes Th. The connection portions 5 are formed of the same copper film as the exterior shielding member 4, and is formed integrally with the exterior shielding member 4 (in a conductive state).

Further, each of the connection portions 5 includes an inner peripheral portion 51, which is arranged so as to cover the inner peripheral surface of each through holes Th, and a contact portion 52, which is formed on an end portion of the inner peripheral portion 51 on a side opposite to the exterior shielding member 4 and is electrically connected to the undersurface ground terminal 132 of the ground line 13. By electrically connecting the ground line 13 and the connections portion 5, the exterior shielding member 4 formed integrally with the connection portions 5 (inner peripheral portions 51) are also electrically connected to the ground line 13. Note that, the exterior shielding member 4 is also grounded when the ground line 13 is grounded (connected to the grounding conductor of the mounting substrate).

In this manner, the exterior shielding member 4 constitutes an electromagnetic shield, and it is possible to perform shielding against undesirable effects due to the electromagnetical field or static electricity (such as high frequency noise). Note that, in the semiconductor module A, the side surface of the semiconductor module A is not covered with the exterior shielding member 4, but the semiconductor module A is thin, and hence it is possible to obtain a sufficient shielding effect with use of the exterior shielding member 4 (without covering the side surface).

Further, a portion of each contact portions 52 protruded from the undersurface of the module substrate 1 may be formed so as to extend along the undersurface ground terminal 132 of the ground line 13, so as to be electrically connected to the undersurface ground terminal 132 of the ground line 13 by soldering and the like. By fixing the contact portion 52 and the undersurface ground terminal 132 to each other as described above, the exterior shielding member 4 and the ground line 13 can be reliably connected to each other.

Note that, in the semiconductor module A, the contact portions 52 are formed on the lower end side of the inner peripheral portions 51, and the contact portions 52 and the undersurface ground terminal 132 of the ground line 13 are provided in contact with each other, to thereby electrically connect the exterior shielding member 4 to the ground line 13. However, the present invention is not limited thereto. The connection portions 5 may be formed so that the contact portions 52 are provided in contact with the inner layer ground wiring 131 of the ground line 13, which is arranged in the inner layer of the module substrate 1. Also with this structure, the exterior shielding member 4 and the ground line 13 can be reliably connected to each other.

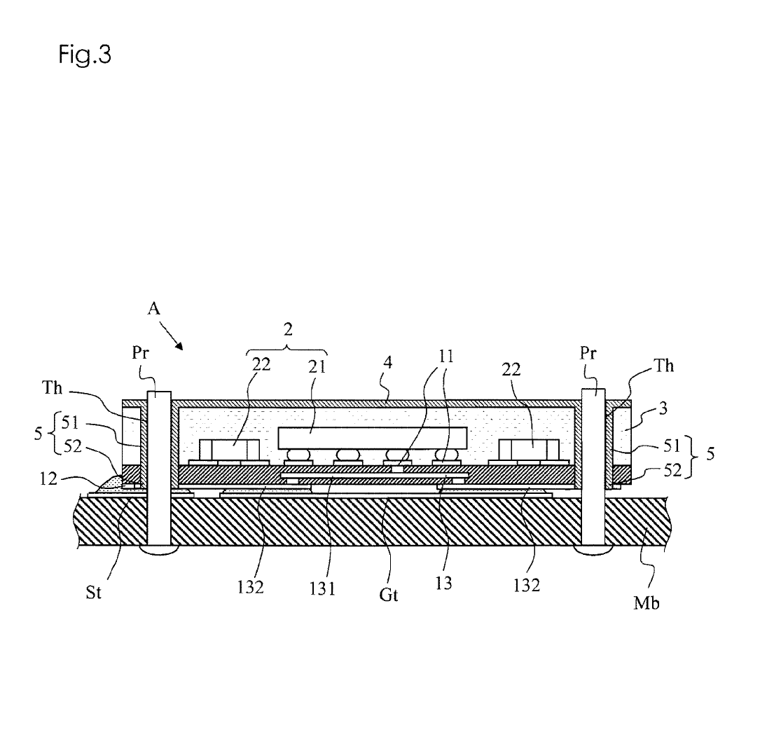

Next, description is made of a state in which the semiconductor module A according to the present invention is mounted on the mounting substrate Mb with reference to other drawings. FIG. 3 is a sectional view of the semiconductor module illustrated in FIG. 2 and the mounting substrate in a state in which the semiconductor module is mounted.

As illustrated in FIG. 3, the semiconductor module A is mounted on the upper surface corresponding to a main surface of the mounting substrate Mb. The mounting substrate Mb includes, on the upper surface thereof, a signal electrode St connected to the module mounting terminal 12 formed on the undersurface of the semiconductor module A, and a ground electrode Gt connected to the undersurface ground terminal 132 of the ground line 13 formed on the undersurface as well. Note that, the signal electrode St is a terminal for supplying a signal (power) for drive to the mounted components (electronic components 2 and the like).

Further, at the upper surface of the mounting substrate Mb, a perpendicularly protruded columnar portion Pr is provided. As illustrated in FIG. 3, the columnar portion Pr is inserted through the through hole Th of the semiconductor module A. Two columnar portions Pr are provided so that the two columnar portions Pr can be simultaneously inserted through the two through holes Th formed in the semiconductor module A. The columnar portion Pr is an insulating pin, which passes through the mounting substrate Mb from the undersurface to the upper surface thereof. The columnar portions Pr are arranged so that the respective columnar portions Pr can be simultaneously inserted through the two through holes Th of the semiconductor module A. By arranging the semiconductor module A so that the respective columnar portions Pr can be inserted through the through holes Th, it is possible to align the semiconductor module A to an accurate position of the mounting substrate Mb. That is, by mounting the semiconductor module A onto the mounting substrate Mb so that the two columnar portions Pr are inserted through the two through holes Th, the module mounting terminal 12 of the semiconductor module A and the corresponding signal electrode St can be accurately brought into contact with each other, and the undersurface ground terminal 132 of the ground line 13 and the ground electrode Gt can be accurately brought into contact with each other.

Under this state, the module mounting terminal 12 is fixed in contact to the corresponding signal electrode St, and the undersurface ground terminal 132 of the ground line 13 is fixed in contact to the ground electrode Gt with solder or an conductive resin adhesive. In this manner, it is possible to mount the semiconductor module A to the mounting substrate Mb. At this time, as illustrated in FIG. 3, the exterior shielding member 4 is not formed on the side surface of the semiconductor module A, and hence even when the amount of the solder or the conductive resin adhesive is too much, it is possible to suppress occurrence of a trouble that the signal electrode St and the exterior shielding member 4 are short-circuited. With this, it is possible to ease the restrictions on the amount of the solder or the conductive resin adhesive when the semiconductor module A is mounted on the mounting substrate Mb, and hence the productivity can be enhanced.

Note that, in the above-mentioned example, a pin which passes through the mounting substrate Mb is exemplified as the columnar portions Pr inserted through the through holes Th, but the present invention is not limited thereto. The columnar portions Pr may be formed integrally with the mounting substrate Mb, or alternatively, may be columnar members embedded from the upper surface of the mounting substrate Mb. Further, the columnar portion Pr may be a conductive member such as a metal wire, and may be formed in such a manner that the columnar portions Pr are connected to the ground electrode Gt of the mounting substrate Mb in advance, and the columnar portions Pr are fixed in contact to the inner peripheral portions 51 of the connection portions 5 formed in the inner peripheral surface of the through holes Th. By electrically connecting the columnar portion Pr having conductivity and the inner peripheral portion 51 of the connection portion 5 to each other as described above, it is possible to perform positioning of the semiconductor module A and also ground the exterior shielding member 4 more reliably. Further, some holes may be provided in the mounting substrate Mb in advance, and positioning may be performed by inserting columnar jigs, which passes through the through holes Th of the semiconductor module A from the upper surface side, through the holes of the mounting substrate Mb. There may be adopted various methods of positioning by inserting a shaft-like member through the through hole Th of the semiconductor module A.

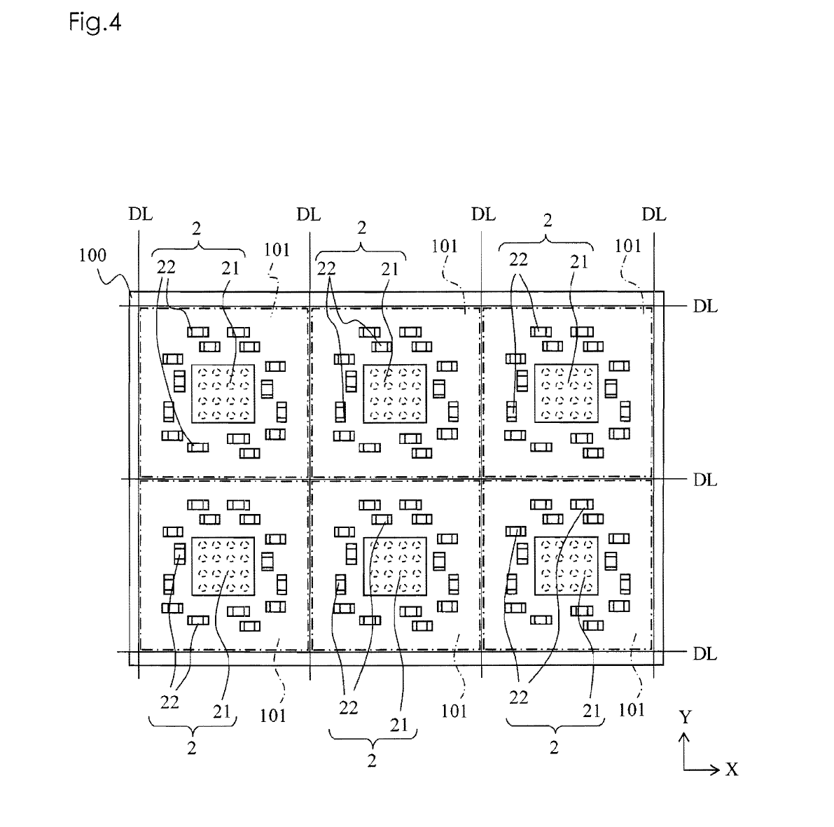

Next, a method of manufacturing the semiconductor module A according to the present invention is described with reference to other drawings. FIGS. 4 to 11 are illustrations of respective steps of manufacturing the semiconductor module A.

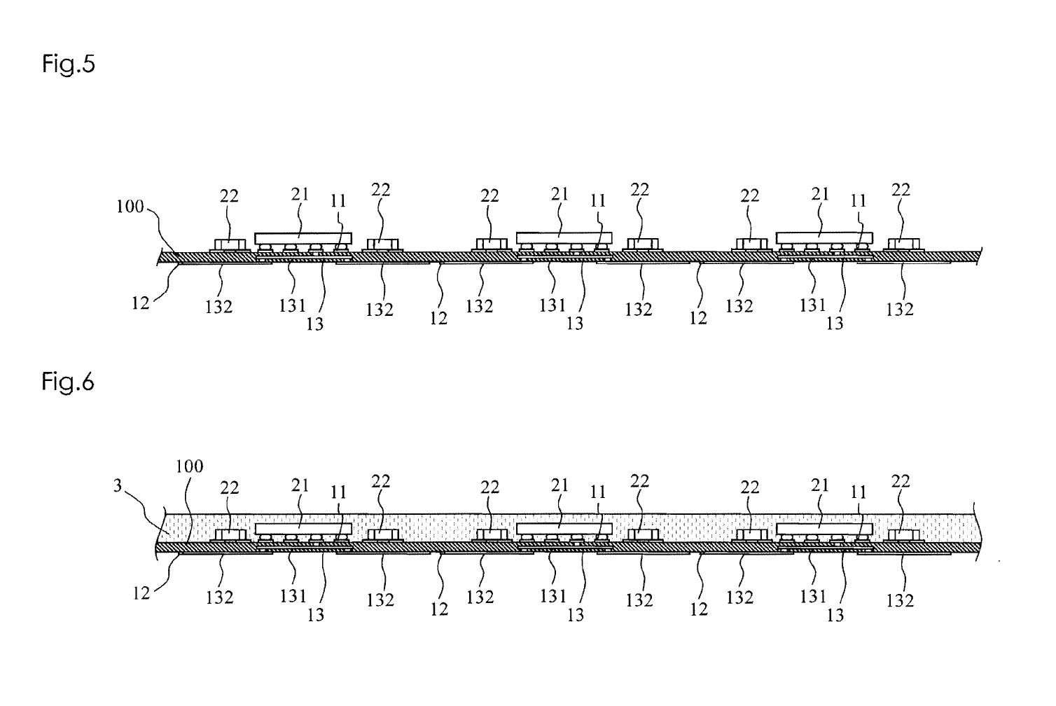

FIG. 4 is a plan view of a state in which the electronic components are mounted on the collective substrate, and FIG. 5 is a sectional view of the collective substrate illustrated in FIG. 4. Note that, in FIG. 4, illustration of the wiring conductors 11 corresponding to the wiring patterns is omitted. However, actually, at portions of the collective substrate 100 forming the module substrates 1, the same wiring conductors 11 are respectively formed. Further, in FIG. 4, the horizontal direction is represented as an X direction, and the direction orthogonal to the X direction in the drawing sheet is represented as a Y direction.

First, the collective substrate 100 is prepared, which has a form in which the module substrates 1 are arranged and combined. This collective substrate 100 is a ceramic multilayer substrate, and includes module regions 101 formed in the same shape and size. Here, in FIG. 4, in order to define the module regions 101, boundary portions are represented by dashed-dotted lines (boundary lines), but in the actual collective substrate 100, the boundary lines of the module regions 101 are not formed.

Note that, the module region 101 is a portion which becomes the module substrate 1 after being cut out, and has a square shape. In a dicing step performed later, cutting is performed in the X direction and the Y direction along dicing lines DL provided at portions at which the module regions 101 are adjacent to one another, and thus the module regions 101 are separated into individual module substrates 1. In this context, a cutting margin may be formed between the adjacent module regions 101 for cutting with a dicer (not shown), and the cutting margin may be set as the dicing line DL. Note that, the dicing line DL may be actually formed in the collective substrate 100, or may be a virtual line stored as positional information (coordinate, length, and the like) in a control portion of the dicer.

The module region 101 includes the wiring conductors 11, the module mounting terminal(s) 12, and the ground line 13. The wiring conductors 11, the module mounting terminal(s) 12, and the ground line 13 are common in shape and size in all of the module regions 101.

As illustrated in FIGS. 4 and 5, on the upper surface (component mounting surface) of the collective substrate 100 having a form in which the module substrates 1 are arranged and combined, the plurality of electronic components 2 such as the semiconductor devices 21 and the passive components 22 are mounted by soldering (mounting step). The wiring conductors 11 are formed of a plurality of wiring patterns, and the plurality of electronic components 2 are mounted so that those terminals are respectively connected to the predetermined wiring conductors 11.

In the semiconductor module A, the electronic components 2 are surface-mounted, and hence the electronic components 2 are mounted in the following procedure, for example. First, on the wiring conductors 11 formed on the upper surface of the collective substrate 100, a solder paste is applied by a printing method. Then, with the use of a mounter, the plurality of electronic components 2 (semiconductor device 21, passive components 22) are arranged so that those terminals are respectively connected to the predetermined wiring conductors 11. Then, the collective substrate 100 on which the electronic components 2 are arranged is heated with a reflow furnace, to thereby melt the solder. In this manner, the electronic components 2 are fixed to the wiring conductors 11.

On the upper surface of the collective substrate 100 including the plurality of electronic components 2 mounted in the mounting step, the encapsulation resin layer 3 made of an insulating resin is formed (encapsulating step). FIG. 6 is a sectional view illustrating the collective substrate after the encapsulating step. As illustrated in FIG. 6, on the upper surface of the collective substrate 100 on which the electronic components 2 are mounted, the encapsulation resin layer 3 made of an insulating resin is formed by a transfer molding method. In the encapsulating step, for example, an epoxy resin is used as the insulating resin. The epoxy resin is a thermosetting resin, and after being provided so as to cover the upper surface of the collective substrate 100, the epoxy resin is heated to be cured. Note that, in order to adjust flowability (viscosity) of the epoxy resin before curing, an inorganic filler is added in some cases. As illustrated in FIG. 6, the encapsulation resin layer 3 covers the entire upper surface of the collective substrate 100. In the transfer molding method, a forming mold (metal, carbon, or the like) is attached to the collective substrate 100, and the epoxy resin is injected inside the forming mold. At this time, the forming mold is heated to heat the epoxy resin. The epoxy resin, which is a thermosetting resin, receives heat from the mold and is cured.

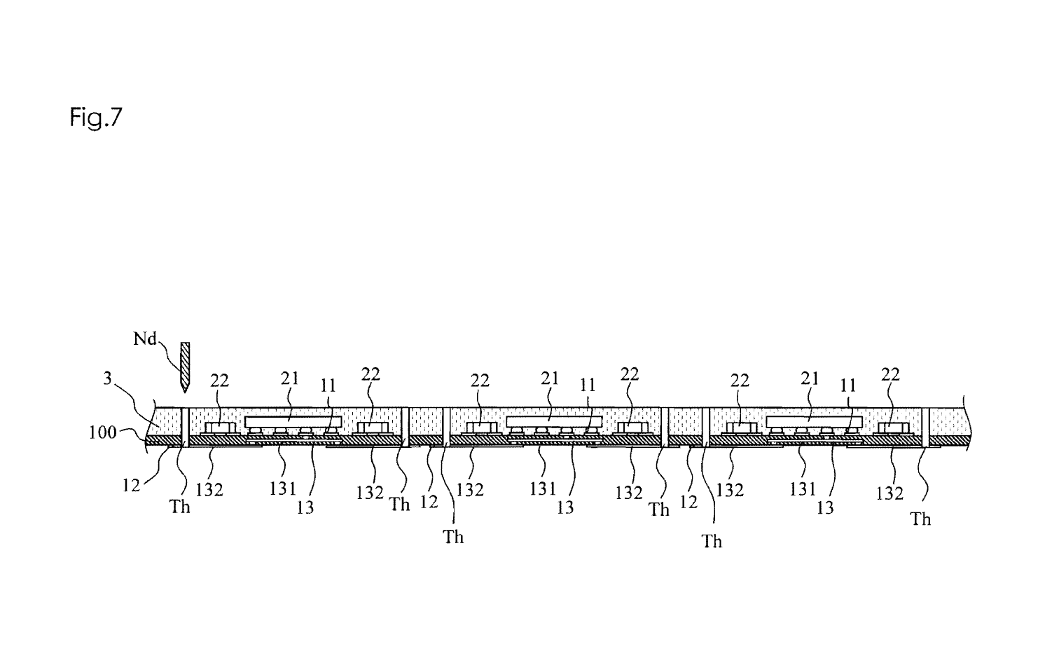

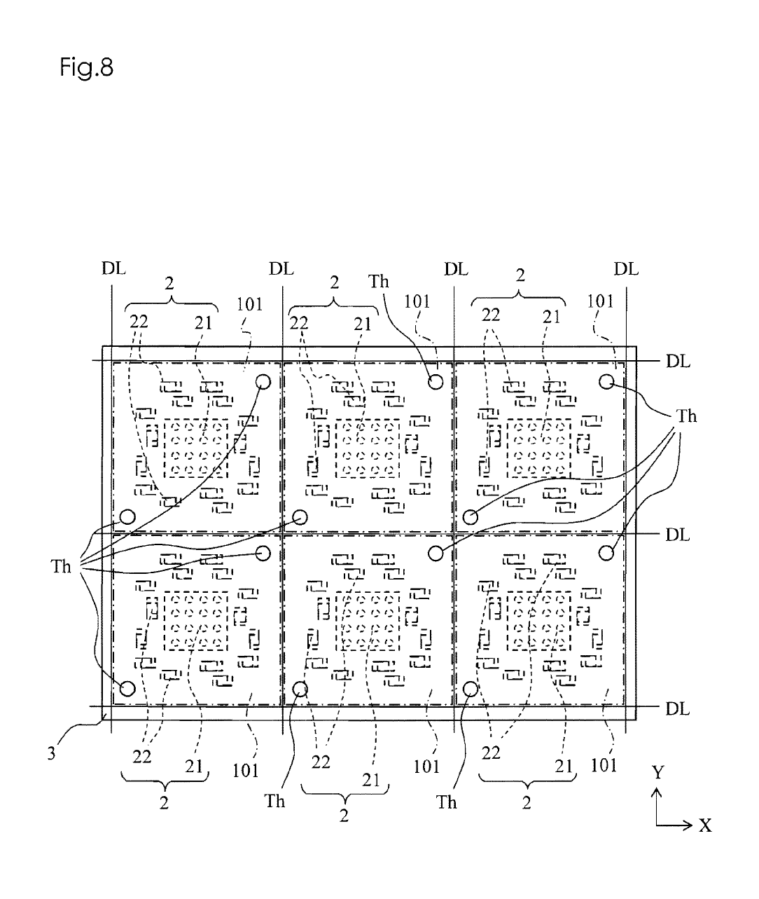

In the collective substrate 100 including the encapsulation resin layer 3 formed in the encapsulating step, the through holes Th are formed (perforating step). FIG. 7 is a sectional view schematically illustrating the perforating step, and FIG. 8 is a plan view illustrating the collective substrate after the perforating step. As illustrated in FIG. 7, in the perforating step, with the use of a numerical control (NC) drill Nd, the through holes Th are formed at predetermined positions of the collective substrate 100 (here, two diagonal positions of each of the module regions 101). The NC drill Nd obtains from the control portion (not shown) X coordinate values and Y coordinate values of the places at which the through holes Th are to be formed, and forms the through holes Th at places indicated by the respective coordinate values. As illustrated in FIG. 8, the through holes Th are formed at the same positions in each of the module regions 101.

Note that, as illustrated in FIGS. 2 and 7, the through holes Th are formed so as to pass through the encapsulation resin layer 3 and the collective substrate 100 (module substrate 1), and further, pass through the undersurface ground terminal 132 of the ground line 13 formed on the undersurface of the collective substrate 100. Note that, the through hole Th is not limited to be formed in two places, and may be formed in one place or three or more places. Regardless of the number of the through holes Th, the through hole Th is formed so as to pass through the undersurface ground terminal 132 of the ground line 13.

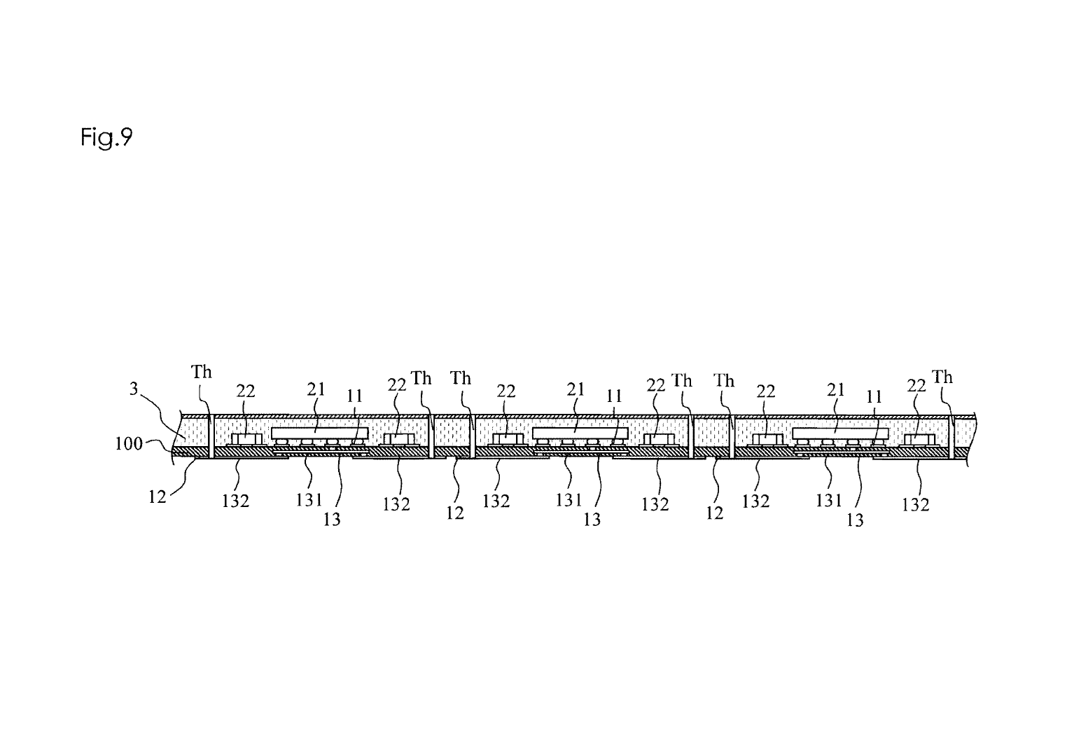

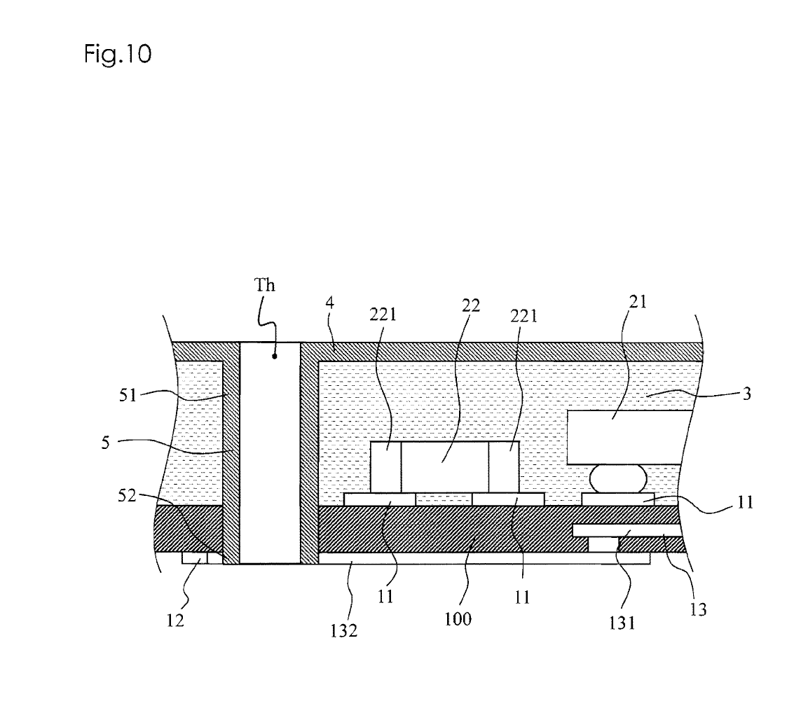

After the through holes Th are formed in the perforating step, a metal coating film is formed on the upper surface of the encapsulation resin layer 3 (film forming step). FIG. 9 is a sectional view of the collective substrate in a state in which the metal coating film is formed in the film forming step, and FIG. 10 is an enlarged sectional view of the through hole portion of FIG. 9. As illustrated in FIG. 9, on the upper surface of the collective substrate 100, on which the encapsulation resin layer 3 is formed on the upper surface thereof and through which the through holes Th are formed, that is, on the upper surface of the encapsulation resin layer 3, the metal coating film is formed by a plating method. The metal coating film is formed in the film forming step so as to uniformly or substantially uniformly cover the entire upper surface of the encapsulation resin layer 3.

In the film forming step, the metal coating film is formed not only on the upper surface of the encapsulation resin layer 3 but also on the inner peripheral surface of the through holes Th (see FIG. 10). Further, the metal coating film is formed to reach the end portion of the through holes Th on the undersurface side, so as to be brought into contact with the undersurface ground terminal 132 of the ground line 13. In the film forming step, the metal coating film is formed on the upper surface of the encapsulation resin layer 3 and the inner peripheral surface of the through hole Th, so as to be brought into contact with the undersurface ground terminal 132. The metal coating film formed in this film forming step constitutes the exterior shielding member 4 and the connection portion 5 illustrated in, for example, FIGS. 1 and 2.

As illustrated in FIG. 10, the exterior shielding member 4 covers the upper surface of the encapsulation resin layer 3, that is, the upper surface of the collective substrate 100 on which the electronic components 2 are mounted. Further, the exterior shielding member 4 is provided in contact with the undersurface ground terminal 132 via the inner peripheral portions 51 and the contact portions 52 of the connection portions 5 formed in the through holes Th. For example, in the semiconductor module A after being separated, the undersurface ground terminal 132 is grounded by being connected to the ground electrode Gt of the mounting substrate Mb, and also the exterior shielding member 4 is grounded. Note that, the exterior shielding member 4 is preferred to be made of a low-resistance metal such as copper. Further, there may be performed a soldering step of fixing the undersurface ground terminal 132 and the contact portions 52 of the connection portions 5 formed in the film forming step with solder. At this time, the contact portions 52 may extend along the undersurface ground terminal 132. As an extending part of the contact portions 52, there may be used a burr formed at the time of film formation in the plating method.

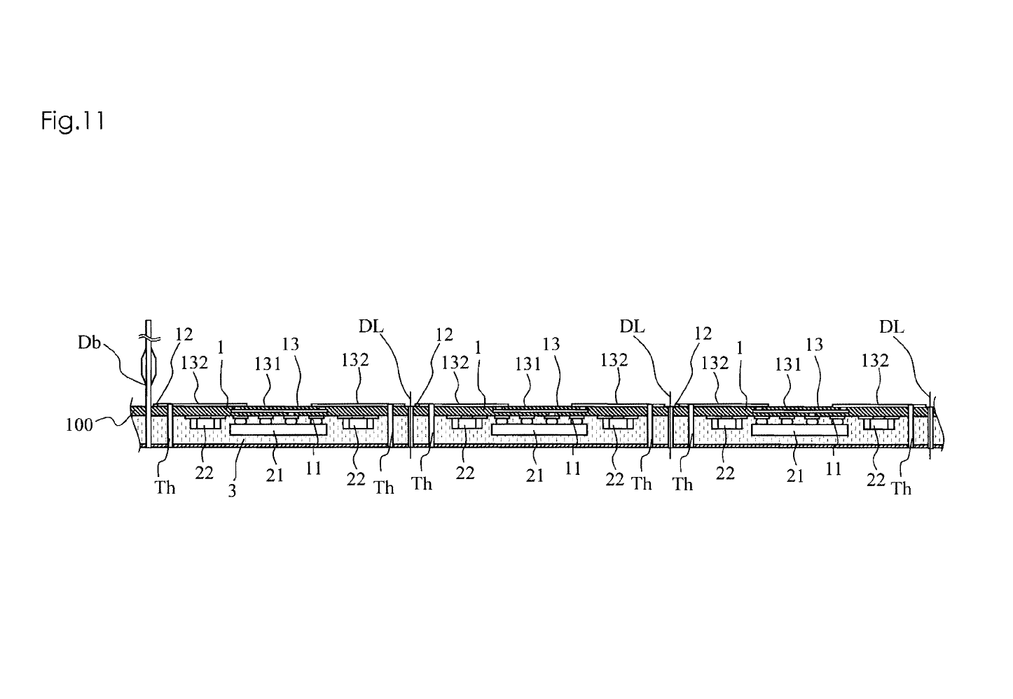

The collective substrate 100 including the exterior shielding member 4 and the connection portions 5 formed in the film forming step is cut for separation (dicing step). FIG. 11 is a sectional view illustrating the dicing step. In the dicing step, a high-speed rotating dicing blade Db is moved along the dicing lines DL, to thereby cut out and separate the module regions 101 to obtain individual pieces of the semiconductor modules A. Note that, in the dicing step illustrated in FIG. 11, the dicing blade Db is brought into contact from the collective substrate 100 side, but the present invention is not limited thereto.

The semiconductor module A formed through the plurality of steps described above has a side surface which is an end surface cut with the dicing blade Db. Therefore, the exterior shielding member 4 is not formed on the side surface of the semiconductor module A, and hence the size of the semiconductor module A can be reduced. Further, the exterior shielding member 4 of the semiconductor module A is grounded via the connection portions 5 formed in the through holes Th. With this, while achieving reduction in size and height of the semiconductor module A, reliable shielding performance can be obtained.

Further, in the semiconductor module A, the exterior shielding member 4 and conductive portions 5 similar thereto are not formed on the side surface. Therefore, it is possible to suppress occurrence of a trouble that the signal electrode St of the mounting substrate Mb and a grounded conductor portion, such as the exterior shielding member 4, are short-circuited depending on the amount of solder used when the semiconductor module A is mounted on the mounting substrate Mb as illustrated in FIG. 3.

Further, in the steps of manufacturing the semiconductor module A according to the present invention, the dicing step is performed only once. With this, compared to the conventional semiconductor module G which is manufactured through the two dicing steps, a time period necessary for the manufacturing can be reduced. Further, in the steps of manufacturing the semiconductor module A according to the present invention, the portions removed by the dicing blade Db are smaller than those in the steps of manufacturing the conventional semiconductor module G. With this, the semiconductor module A according to the present invention is capable of reducing waste of materials as compared to the conventional semiconductor module G. Further, in the dicing step, the dicing blade Db having one thickness is used to cut the collective substrate 100 for separation. Therefore, it is possible to simplify the device necessary for the manufacturing.

As understood from the above, the semiconductor module A of the present invention can be small in size and height, and can be manufactured in reduced number of steps. Further, materials necessary for the manufacturing can be reduced, which leads to high productivity. Further, with the use of the semiconductor module A of the present invention, it is possible to prevent mounting failure when the semiconductor module A is mounted on the mounting substrate, which can enhance the productivity of the electronic devices using the semiconductor module A.

### Second Embodiment

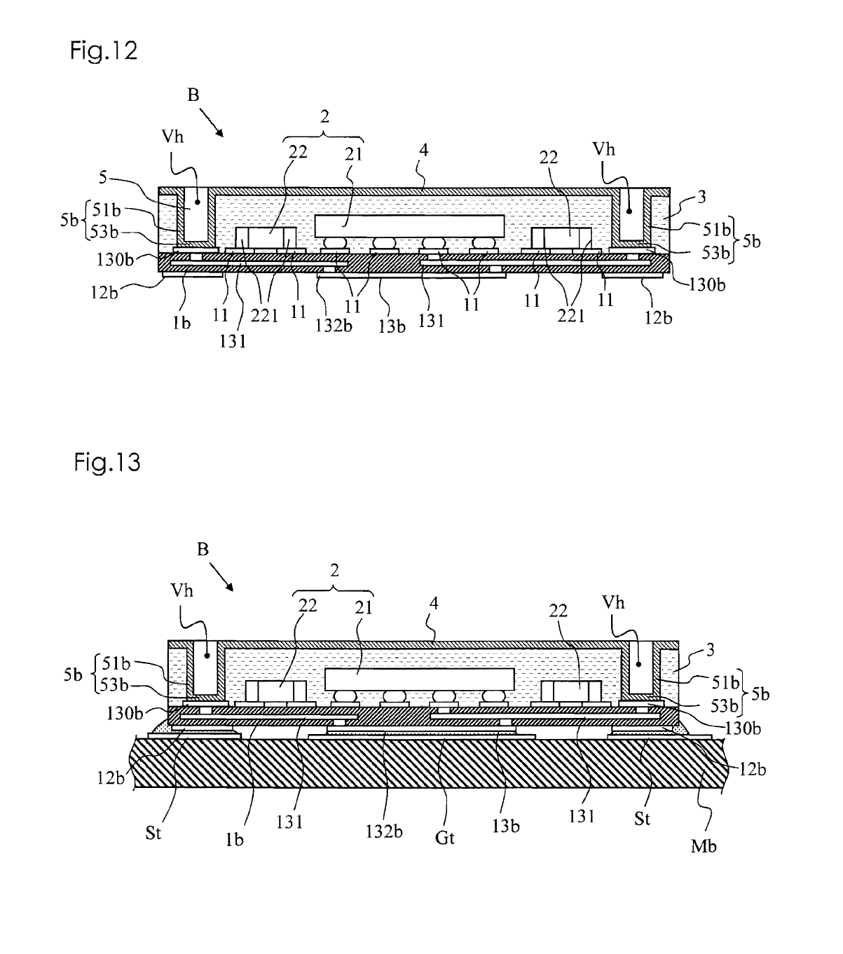

Another example of the semiconductor module according to the present invention is described with reference to the drawings. FIG. 12 is a schematic sectional view of the another example of the semiconductor module according to the present invention. A semiconductor module B illustrated in FIG. 12 has the same structure as the semiconductor module A except that a module substrate 1b, a module mounting terminal 12b, a ground line 13b, and a connection portion 5b are different. Of parts constituting the semiconductor module B, parts substantially similar to the parts constituting the semiconductor module A are denoted by the same reference symbols, and detailed description thereof is omitted.

As illustrated in FIG. 12, the ground line 13b of the module substrate 1b includes an upper surface ground terminal 130b on the upper surface of the module substrate 1b corresponding to the component mounting surface. The upper surface ground terminal 130b is connected to the inner layer ground wiring 131 formed in the inner layer of the module substrate 1b. Note that, the ground line 13b is formed of a metallic film having low electrical resistance such as a copper film. Further, in the semiconductor module B, when the upper surface ground terminal 130b, which is formed on the upper surface of the module substrate 1b, and wiring of the wiring conductors 11 to be grounded, which is formed on the upper surface of the module substrate 1b as well, are brought into contact with each other on the upper surface, the via-hole (not shown), which is used in the semiconductor module A to connect the wiring conductor 11 and the inner layer ground wiring 131, can be omitted.

As illustrated in FIG. 12, in the encapsulation resin layer 3, there is formed recessed holes Vh from the upper surface thereof, which reaches the upper surface ground terminal 130b arranged on the upper surface of the module substrate 1. Each of the recessed holes Vh is formed so that the bottom portion thereof is positioned to expose the upper surface ground terminal 130b. Note that, the recessed holes Vh of the semiconductor module B is formed at the same position as the through holes Th of the semiconductor module A in plan view. Further on the upper surface of the semiconductor module B, the exterior shielding member 4 formed of the metal coating film is provided. Note that, the recessed holes Vh may be formed at the same position as the through holes Th of the semiconductor module A in plan view, or may be formed at other positions. Further, the recessed hole Vh is not used for positioning, and hence may be formed in one place or three or more places.

The connection portion 5b includes a portion covering the inner peripheral surface of the recessed hole Vh (inner peripheral portion 51b) and a portion covering the bottom surface of the recessed hole Vh (contact portion 53b). The inner peripheral portion 51b and the contact portion 53b of the connection portion 5b are integrally formed with each other. Further, as illustrated in FIG. 12, the exterior shielding member 4 and the connection portions 5b (inner peripheral portions 51b) are integrally formed with each other. Further, by bringing the contact portions 53b into contact with the upper surface ground terminal 130b of the ground line 13b, the exterior shielding member 4 formed integrally with the connection portions 5b (inner peripheral portions 51b) are electrically connected to the ground line 13b.

With the structure of the semiconductor module B, the contact portion 53b of the connection portion 5b and the upper surface ground terminal 130b of the ground line 13b are brought into plane-contact with each other, and hence connection is stabilized. With this, the connection resistance between the exterior shielding member 4 and the ground line 13b can be reduced. Note that, the ground line 13b is grounded by being connected to the grounding conductor of the mounting substrate, and thus the exterior shielding member 4 is also grounded. With this, it is possible to enhance the effect of the exterior shielding member 4, of shielding against undesirable effects due to the electromagnetical field or static electricity (such as high frequency noise).

Next, description is made of mounting the semiconductor module B illustrated in FIG. 12 onto the mounting substrate Mb with reference to the drawings. FIG. 13 is a sectional view of the semiconductor module illustrated in FIG. 12 and the mounting substrate in a state in which the semiconductor module is mounted. Note that, the structure of FIG. 13 is the same as that of FIG. 12 except that the semiconductor module B is different. Substantially the same parts are denoted by the same reference symbols, and detailed description thereof is omitted.

As illustrated in FIG. 13, the semiconductor module B is mounted on the upper surface of the mounting substrate Mb. The module mounting terminal 12b of the semiconductor module B is connected to the signal electrode St, and an undersurface ground terminal 132b of the ground line 13b is connected to the ground electrode Gt. As illustrated in FIG. 13, in the undersurface of the semiconductor module B, the module mounting terminal 12b is formed at an edge area, and the undersurface ground terminal 132b is formed near the center, the module mounting terminal 12b and the undersurface ground terminal 132b being formed in a separated manner. With this, even if the solder amount is too much when mounting the semiconductor module B, it is possible to prevent short-circuit between the module mounting terminal 12b and the undersurface ground terminal 132b. Further, at the time of soldering between the module mounting terminal 12b and the signal electrode St, even if the solder amount is too much and the solder rises to adhere to the side surface of the semiconductor module B, the solder is not brought into contact with the exterior shielding member 4. With this, it is possible to prevent short-circuit of the signal electrode St of the mounting substrate Mb and the exterior shielding member 4 electrically connected to the ground electrode Gt.

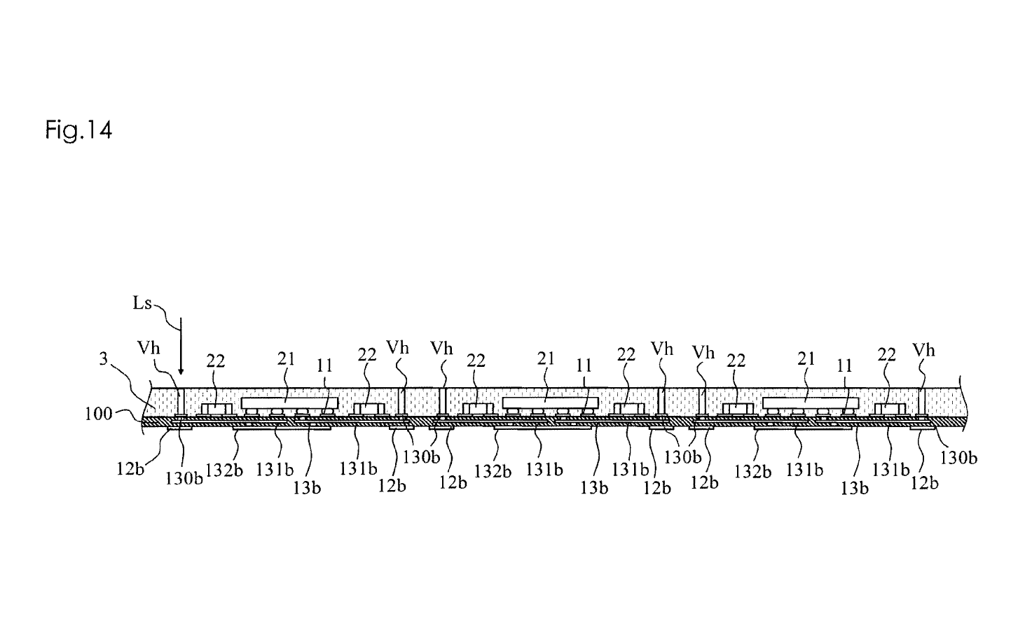

Next, description is made of steps of manufacturing the semiconductor module B illustrated in FIG. 12 with reference to other drawings. FIGS. 14 to 18 are sectional views schematically illustrating part of the steps of manufacturing the semiconductor module illustrated in FIG. 12. Manufacturing steps from the mounting step to the encapsulating step for the semiconductor module B are the same as those for the semiconductor module A. That is, the plurality of electronic components 2 are mounted on the upper surface of the collective substrate 100, and the upper surface of the collective substrate 100 is encapsulated with an insulating resin.

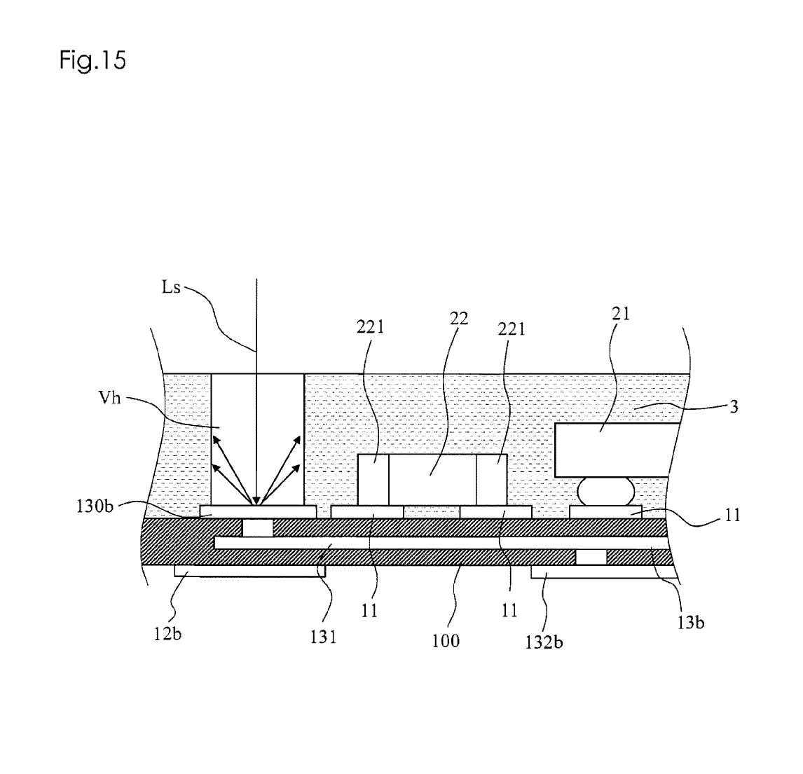

The recessed holes Vh is formed in the collective substrate 100 including the encapsulation resin layer 3 formed in the encapsulating step (drilling step). FIG. 14 is a sectional view schematically illustrating the collective substrate during the drilling step, and FIG. 15 is a sectional view illustrating a state in which the encapsulation resin layer which encapsulates the upper surface of the collective substrate is irradiated with a laser beam Ls.

In the drilling step, the laser beam Ls is applied from the upper surface side of the collective substrate 100, to thereby form the recessed holes Vh in the encapsulation resin layer 3. The laser beam Ls is applied orthogonal to the upper surface of the collective substrate 100. The encapsulation resin layer 3 is removed by being irradiated with the laser beam Ls, and thus the recessed holes Vh are formed. As illustrated in FIG. 12, the bottom surface of the recessed holes Vh are formed to expose the upper surface ground terminal 130b, and hence the laser beam Ls is applied toward the upper surface ground terminal 130b formed on the upper surface of the module region 101.

As illustrated in FIG. 15, the laser beam Ls is reflected by the upper surface ground terminal 130b serving as a metallic mirror plane. With the use of this property, a laser beam source (not shown) emitting the laser beam Ls can be accurately positioned above the upper surface ground terminal 130b. With this, the laser beam Ls can be accurately applied toward the upper surface ground terminal 130b.

Specifically, the laser beam Ls has a property of being reflected in larger amount at the metallic mirror plane, and the reflected light amount of the laser beam Ls is different between the upper surface ground terminal 130b and the collective substrate 100. With the use of this property, while detecting the reflected light of the laser beam Ls, the laser beam Ls is applied from above the encapsulation resin layer 3. When the intensity (light amount) of the reflected light becomes equal to or larger than a predetermined value, the drilling process with the laser beam Ls is started. Note that, when the laser beam Ls is applied from above the encapsulation resin layer 3 in order to determine the application position of the laser beam Ls, the output of the laser beam Ls at the time of positioning may be smaller than that at the time of drilling so as to prevent the encapsulation resin layer 3 from being removed. Further, with the use of NC control, a rough position of the laser beam source with respect to the module regions 101 may be determined in advance, and with the use of the above-mentioned reflecting property of the laser beam Ls, accurate positioning may be performed. Note that, when accurate positioning of the laser beam source with respect to the module region 101 is possible by the NC control, the positioning using the reflecting property may be omitted.

After the application position of the laser beam Ls is determined, the laser beam Ls with the predetermined output is applied to the encapsulation resin layer 3, to thereby remove the encapsulation resin layer 3. When the encapsulation resin layer 3 is removed by the laser beam Ls to reach the upper surface ground terminal 130b, the laser beam Ls is reflected by the upper surface ground terminal 130b, and the removing slows down. Thus, the drilling process (drilling step) is completed. Note that, in the drilling step, in order to increase the exposing amount of the upper surface ground terminal 130b from the bottom surface of the recessed hole Vh, the resin in the recessed hole Vh portion, which forms the encapsulation resin layer 3, is preferred to be completely (or substantially completely) removed.

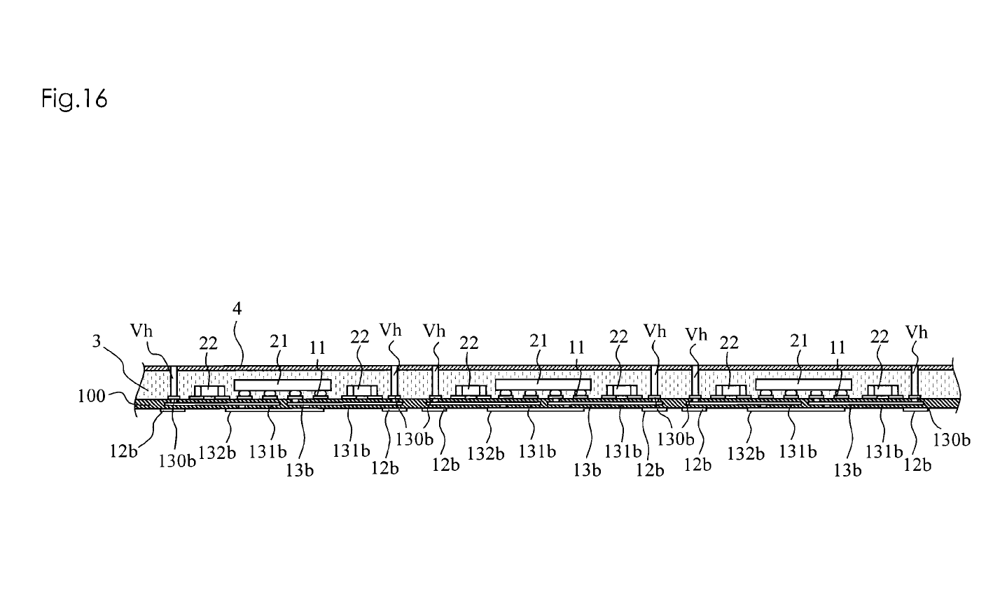

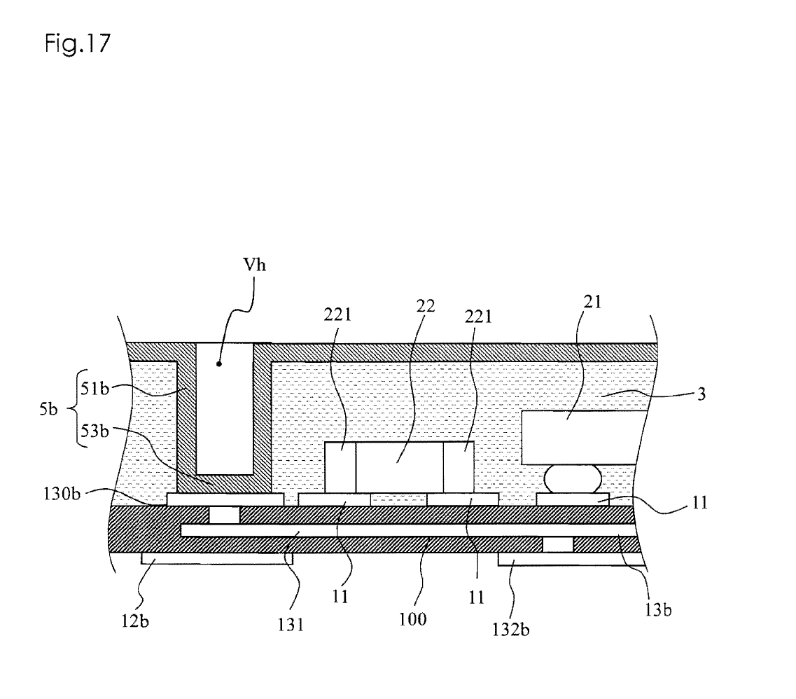

After the recessed holes Vh are formed in the drilling step, the metal coating film is formed on the upper surface of the encapsulation resin layer 3 (film forming step). FIG. 16 is a sectional view of the collective substrate after the film forming step, and FIG. 17 is an enlarged sectional view of the recessed hole portion of the collective substrate illustrated in FIG. 16. As a method of forming the metal coating film, a method similarly to that in the steps of manufacturing the semiconductor module A is performed. That is, the metal coating film is formed from the upper surface of the encapsulation resin layer 3 by a plating method. The metal coating film is formed in the film forming step so as to uniformly or substantially uniformly cover the entire upper surface of the encapsulation resin layer 3.

Further, in the film forming step, the metal coating film is formed not only on the upper surface of the encapsulation resin layer 3 but also on the inner peripheral surface and the bottom surface of the recessed hole Vh (see FIG. 17). The upper surface ground terminal 130b is exposed from the bottom surface of the recessed hole Vh, and the metal coating film is brought into contact with the upper surface ground terminal 130b at the bottom surface of the recessed holes Vh. The metal coating film formed in this film forming step constitutes the exterior shielding member 4 and the connection portions 5b illustrated in FIG. 12.

As illustrated in FIG. 12, the exterior shielding member 4 covers the upper surface of the encapsulation resin layer 3, that is, the upper surface of the collective substrate 100 on which the electronic components 2 are mounted. Further, as illustrated in FIG. 17, the exterior shielding member 4 and the connection portions 5b (inner peripheral portions 51b) are formed integrally with each other. Further, the connection portion 5b is provided in contact with the upper surface ground terminal 130b at the contact portion 53b. For example, in the semiconductor module B after being cut out and separated, the undersurface ground terminal 132b is grounded by being brought into contact with the ground electrode Gt of the mounting substrate Mb, and thus the exterior shielding member 4 is also grounded. Note that, the exterior shielding member 4 and the connection portions 5b are preferred to be made of a low-resistance metal such as copper.

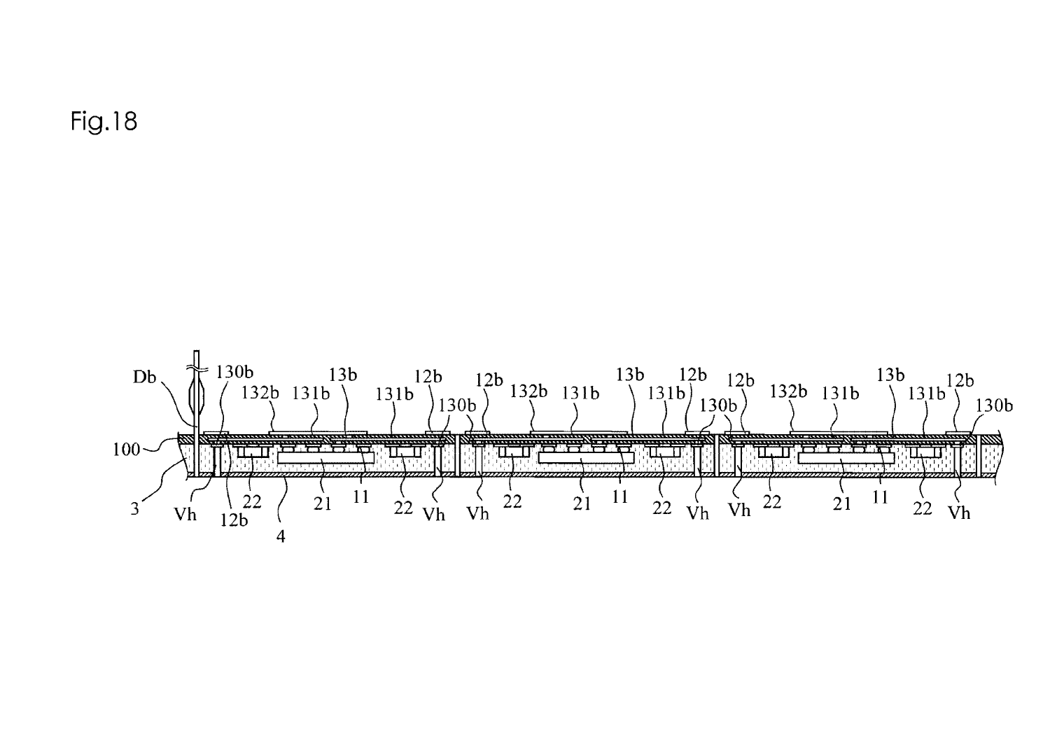

The collective substrate 100 including the exterior shielding member 4 and the connection portion 5b formed in the film forming step is cut for separation (dicing step). FIG. 18 is a sectional view illustrating the dicing step. The dicing step in the steps of manufacturing the semiconductor module B is performed by the same method as in the dicing step in the steps of manufacturing the semiconductor module A. That is, the high-speed rotating dicing blade Db is moved along the dicing lines DL, to thereby cut out and separate the module regions 101 to obtain individual pieces of the semiconductor modules B.

The semiconductor module B formed through the plurality of steps described above has a side surface which is an end surface cut with the dicing blade Db. Therefore, the exterior shielding member 4 is not formed on the side surface of the semiconductor module B, and hence the size of the semiconductor module B can be reduced. Further, the exterior shielding member 4 of the semiconductor module B is grounded via the connection portions 5b (inner peripheral portions 51b and contact portions 53b) formed in the recessed holes Vh. With this, while achieving reduction in height of the semiconductor module B, reliable shielding performance can be obtained.

Further, in the semiconductor module B, the exterior shielding member 4 and conductive portions similar thereto are not formed on the side surface. Therefore, it is possible to suppress occurrence of a trouble that the signal electrode St of the mounting substrate Mb and a grounded conductor portion, such as the exterior shielding member 4, are short-circuited depending on the amount of solder used when the semiconductor module B is mounted on the mounting substrate Mb as illustrated in FIG. 13.

Further, in the steps of manufacturing the semiconductor module B according to the present invention, the dicing step is performed only once. With this, compared to the conventional semiconductor module G which is manufactured through the two dicing steps, a time period necessary for the manufacturing can be reduced. Further, in the steps of manufacturing the semiconductor module B according to the present invention, the portions removed by the dicing blade are smaller than those in the steps of manufacturing the conventional semiconductor module G. With this, the semiconductor module B according to the present invention is capable of reducing waste of materials as compared to the conventional semiconductor module G. Further, in the dicing step, the dicing blade having one thickness is used to cut the collective substrate 100 for separation. Therefore, it is possible to simplify the device necessary for the manufacturing.

As understood from the above, the semiconductor module B of the present invention can be small in size and height, and can be manufactured in reduced number of steps. Further, materials necessary for the manufacturing can be reduced, which leads to high productivity. Further, with the use of the semiconductor module B of the present invention, it is possible to prevent mounting failure when the semiconductor module B is mounted on the mounting substrate, which can enhance the productivity of the electronic devices using the semiconductor module B.

### Third Embodiment

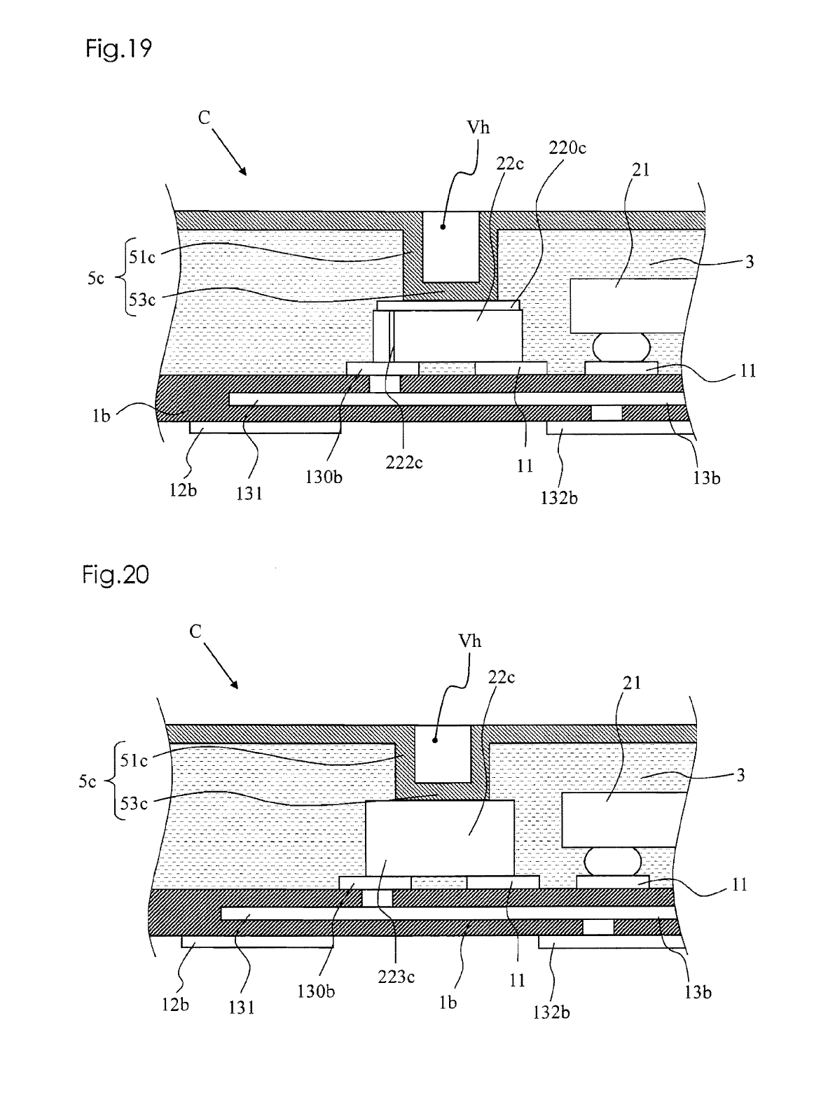

Still another example of the semiconductor module according to the present invention is described with reference to other drawings. FIG. 19 is an enlarged sectional view of the still another example of the semiconductor module according to the present invention. A semiconductor module C illustrated in FIG. 19 has the same structure as the semiconductor module B except that a connection portion 5c is different. Substantially similar parts are denoted by the same reference symbols, and detailed description of the substantially similar parts is omitted.

As illustrated in FIG. 19, a passive component 22c is mounted in a manner connected to the upper surface ground terminal 130b of the module substrate 1b. The passive component 22c includes, on the upper surface thereof, an electrode terminal 220c, and, on the outer surface thereof, wiring 222c connecting the electrode terminal 220c and the upper surface ground terminal 130b to each other. That is, the electrode terminal 220c functions as a ground terminal. Further, as illustrated in FIG. 19, in the connection portion 5c of the semiconductor module C, a portion covering the inner peripheral surface of the recessed hole Vh (inner peripheral portion 51c) and a portion covering the bottom surface of the recessed hole Vh (contact portion 53c) are formed integrally with each other. Further, the exterior shielding member 4 and the connection portion 5c (inner peripheral portion 51c) are formed integrally with each other.

The recessed hole Vh of the semiconductor module C is formed above the passive component 22c, and the contact portion 53c of the connection portion 5c is provided in contact with the electrode terminal 220c. The electrode terminal 220c is (electrically) connected to the ground line 13b. With this, the exterior shielding member 4, which is integrally formed with the connection portion 5c, is also connected to the ground line 13b.

With this semiconductor module C, a part of the passive component 22c is used to ground the exterior shielding member 4, and hence there is no need to form the ground terminal for grounding the exterior shielding member on the module substrate while avoiding the plurality of electronic components 2. Therefore, it is possible to reduce the size of the semiconductor module C in plan view.

Steps of manufacturing the semiconductor module C are the same as those of manufacturing the semiconductor module B except that a drilling position in the drilling step is different, and hence description of the detailed manufacturing steps is omitted. The recessed hole Vh of the semiconductor module C is shallower than the recessed hole Vh of the semiconductor module B. Therefore, a time period necessary for the drilling step can be reduced, and as compared to the semiconductor module B, manufacturing efficiency can be enhanced. Note that, in the semiconductor module C, as the passive component 22c, there is exemplified a member in which the wiring 222c connecting the electrode terminal 220c and the upper surface ground terminal 130b to each other is formed on the outer surface of the passive component 22c. However, the present invention is not limited thereto. The electrode terminal 220c and the upper surface ground terminal 130b may be connected to each other via a through hole formed inside the passive component 22c.

FIG. 20 is an enlarged sectional view of a modification example of this embodiment. As illustrated in FIG. 20, the recessed hole Vh is formed on the upper surface of the passive component 22c (for example, crystal oscillator), which is covered with a cover 223c made of a metal with its outer peripheral portion grounded. By providing the contact portion 53c of the connection portion 5c, which covers the bottom surface of the recessed hole Vh, in contact with the cover 223c, the exterior shielding member 4 can be connected to the ground line 13b. With this structure, the passive component 22c may be formed without the electrode terminal 220c and the wiring 222c, thereby being capable of saving effort for manufacturing the semiconductor module C.

Other effects of the third embodiment are the same as those in the above-mentioned first and second embodiments.

### Fourth Embodiment

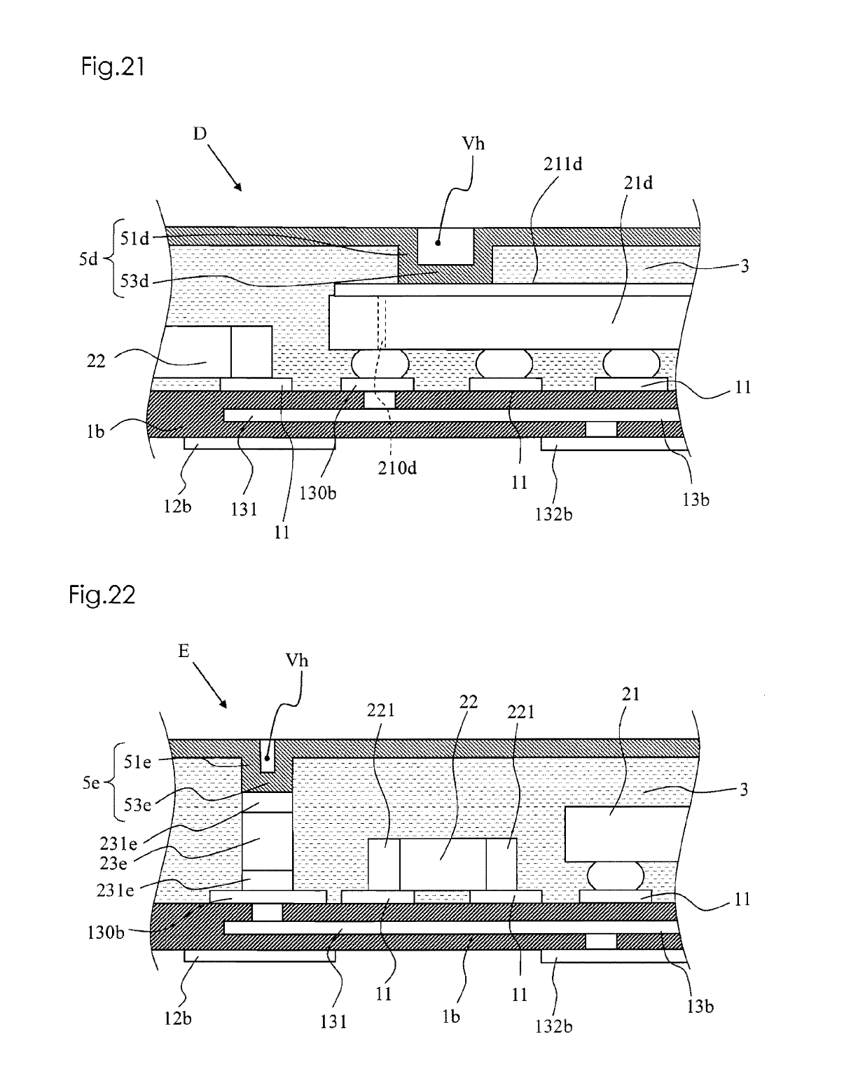

Further another example of the semiconductor module according to the present invention is described with reference to the drawings. FIG. 21 is an enlarged sectional view of the further another example of the semiconductor module according to the present invention. A semiconductor module D illustrated in FIG. 21 has the same structure as the semiconductor module C except that a semiconductor device 21d and a connection portion 5d are different. Substantially similar parts are denoted by the same reference symbols, and detailed description of the similar parts is omitted. Further, manufacturing steps for the semiconductor module D are the same as those for the above-mentioned semiconductor modules except that the position of the recessed hole formed in the drilling step is different, and hence detailed description thereof is omitted.

As illustrated in FIG. 21, the semiconductor module D includes the semiconductor device 21d, which is a through silicon WL-CSP in which a through silicon via 210d, which is a through hole having a conductive inner peripheral surface, is formed. In the semiconductor module D, a metal terminal portion 211d formed on the upper surface thereof and an undersurface terminal (not shown) formed on the undersurface thereof are electrically connected to each other via the through silicon via 210d. The undersurface terminal connected to the metal terminal portion 211d via the through silicon via 210d is connected to the upper surface ground terminal 130b of the module substrate 1 via solder. With this, the metal terminal portion 211d on the upper surface of the semiconductor device 21d is connected to the ground line 13b.

Further, in the semiconductor module D, the recessed hole Vh is formed above the semiconductor device 21d, and a contact portion 53d of the connection portion 5d, which covers the bottom surface of the recessed hole Vh, is provided in contact with the metal terminal portion 211d of the semiconductor device 21d. With this, the connection portion 5d is electrically connected to the ground line 13b, and thus the exterior shielding member 4 integrally formed with the connection portion 5d is also electrically connected to the ground line 13b. Note that, when the ground line 13b is grounded (connected to the grounding electrode of the mounting substrate), the exterior shielding member 4 is also grounded.

With the use of the through silicon WL-CSP as the semiconductor device 21d, the exterior shielding member 4 can be reliably and easily connected to the ground line. Further, similarly to the semiconductor module C, the recessed hole Vh is shallow, and hence a time period necessary for the manufacturing step can be reduced.

Other effects of the fourth embodiment are the same as those in the above-mentioned first to third embodiments.

### Fifth Embodiment

Yet another example of the semiconductor module according to the present invention is described with reference to the drawings. FIG. 22 is an enlarged sectional view of the yet another example of the semiconductor module according to the present invention. A semiconductor module E illustrated in FIG. 22 has the same structure as the semiconductor module B except that a chip component 23e, which is provided upright in the thickness direction (vertical direction) of the semiconductor module E, is provided. Substantially similar parts are denoted by the same reference symbols, and detailed description thereof is omitted.

As illustrated in FIG. 22, in the semiconductor module E, in addition to the plurality of electronic components 2, the chip component 23e is provided so that one of external terminal electrodes 231e thereof is soldered to the upper surface ground terminal 130b, and the chip component 23e is provided upright in the thickness direction of the semiconductor module E. Further, the upper surface of the semiconductor module E is encapsulated with the encapsulation resin layer 3, which is an insulating resin. Further, the semiconductor module E includes the recessed hole Vh formed so as to expose the other of the external terminal electrodes 231e of the chip component 23e, and a connection portion 5e including an inner peripheral portion 51e covering the inner peripheral surface of the recessed hole Vh and a contact portion 53e covering the bottom surface of the recessed hole Vh. Note that, as the chip component 23e, there may be exemplified a member in which the one and the other of the external terminal electrodes 231e are conductive, for example, a resistor (having low resistance).

In the semiconductor module E, the recessed hole Vh is formed above the chip component 23e, and the contact portion 53e of the connection portion 5e, which covers the bottom surface of the recessed hole Vh, is provided in contact with the other of the external terminal electrodes 231e of the chip component 23e. With this, the connection portion 5e is electrically connected to the ground line 13b via the chip component 23e, and the exterior shielding member 4 integrally formed with the connection portion 5e is also electrically connected to the ground line 13b. Note that, the ground line 13b is grounded by being connected to the grounding conductor of the mounting substrate, and thus the exterior shielding member 4 is also grounded.

The semiconductor module E uses the chip component 23e and the connection portion 5e to connect the exterior shielding member 4 and the ground line 13b to each other, and hence the exterior shielding member 4 can be reliably and easily grounded. Further, similarly to the semiconductor module C, the recessed hole Vh is shallow, and hence a time period necessary for the manufacturing step can be reduced.

Further, as the chip component 23e, there may be used a member having a length in the thickness direction of the semiconductor module E, which is the same as the thickness of the encapsulation resin layer 3. In this case, the encapsulating step with the insulating resin may be performed so that the external terminal electrode 231e on the leading end side is exposed from the resin. As described above, by performing encapsulation with the resin so that the external terminal electrode 231e on the leading end side of the chip component 23e is exposed from the resin, it is possible to omit a step of exposing the external terminal electrode 231e of the chip component 23e (in the above description, the drilling step). With this, it is possible to reduce the number of the manufacturing steps, and accordingly improve the production efficiency.

Note that, when the resistor is used as the chip component 23e, the resistance thereof is preferred to be as small as possible. Further, instead of the chip component 23e, there may be used a copper wire (jumper wire) which can be provided in an up-right state.

Other effects of the fifth embodiment are the same as those in the above-mentioned first to fourth embodiments.

### Sixth Embodiment

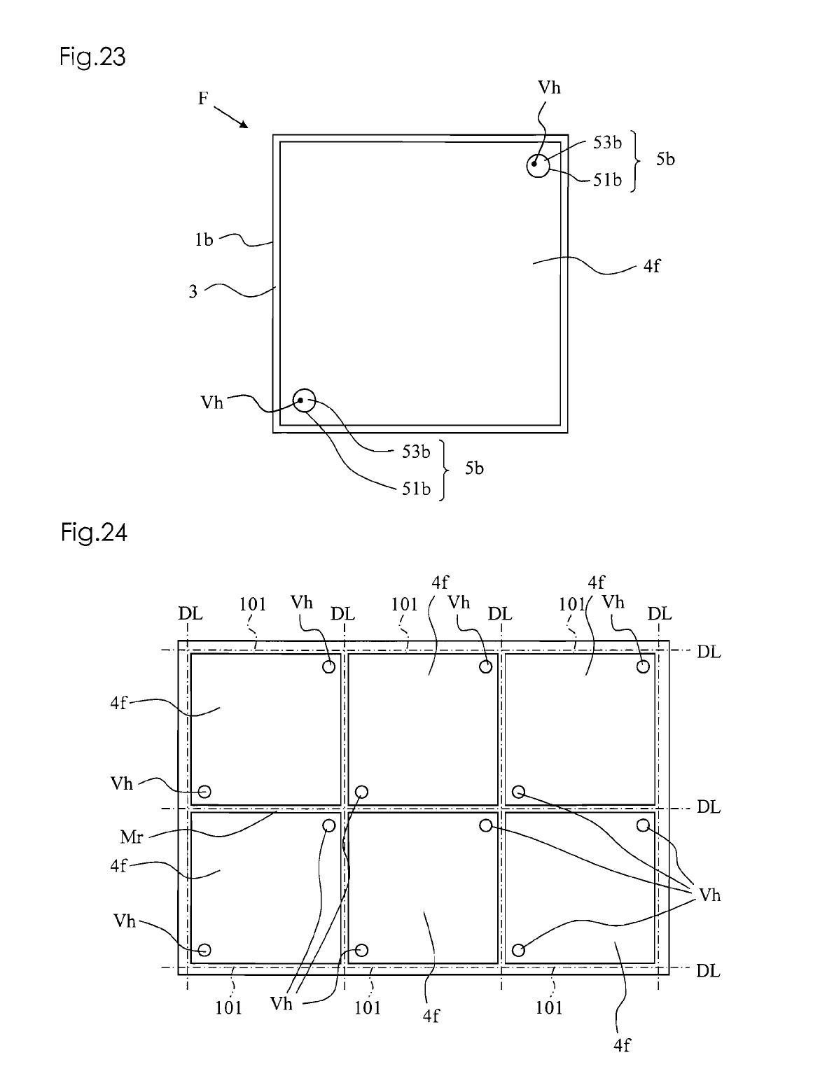

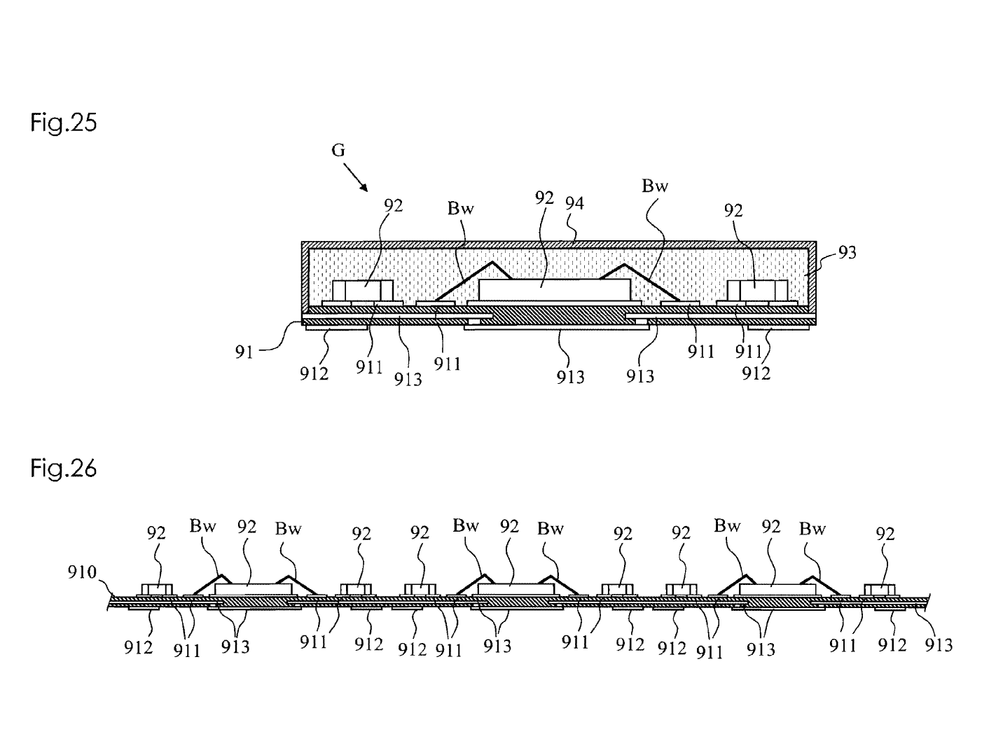

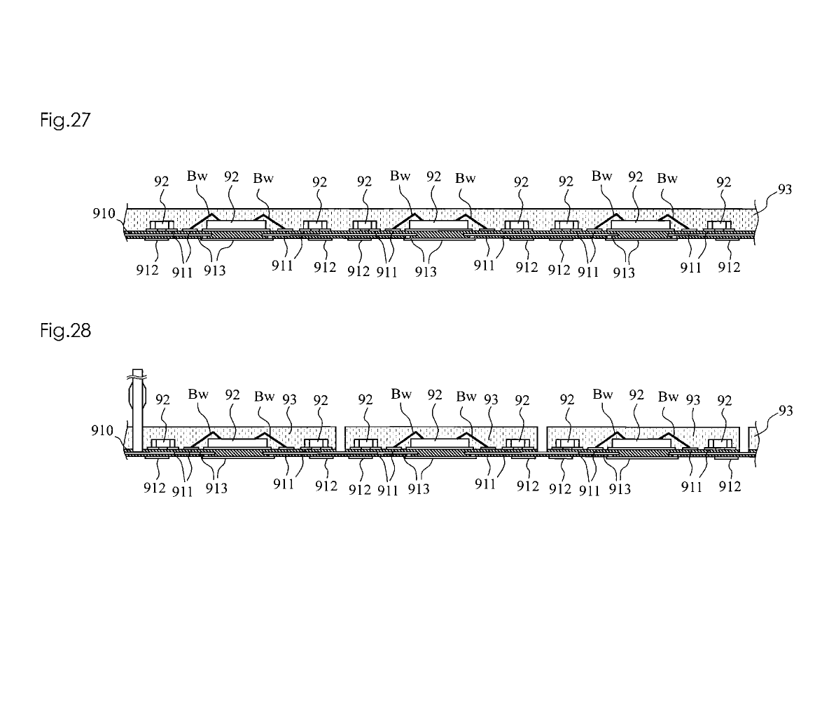

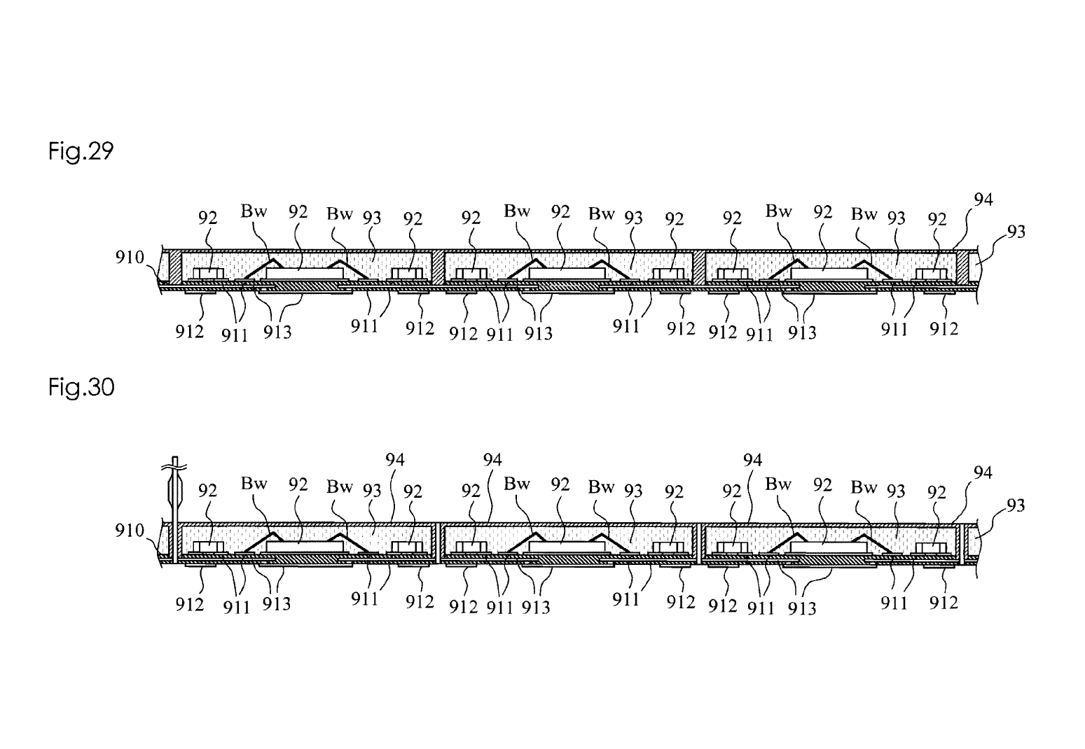

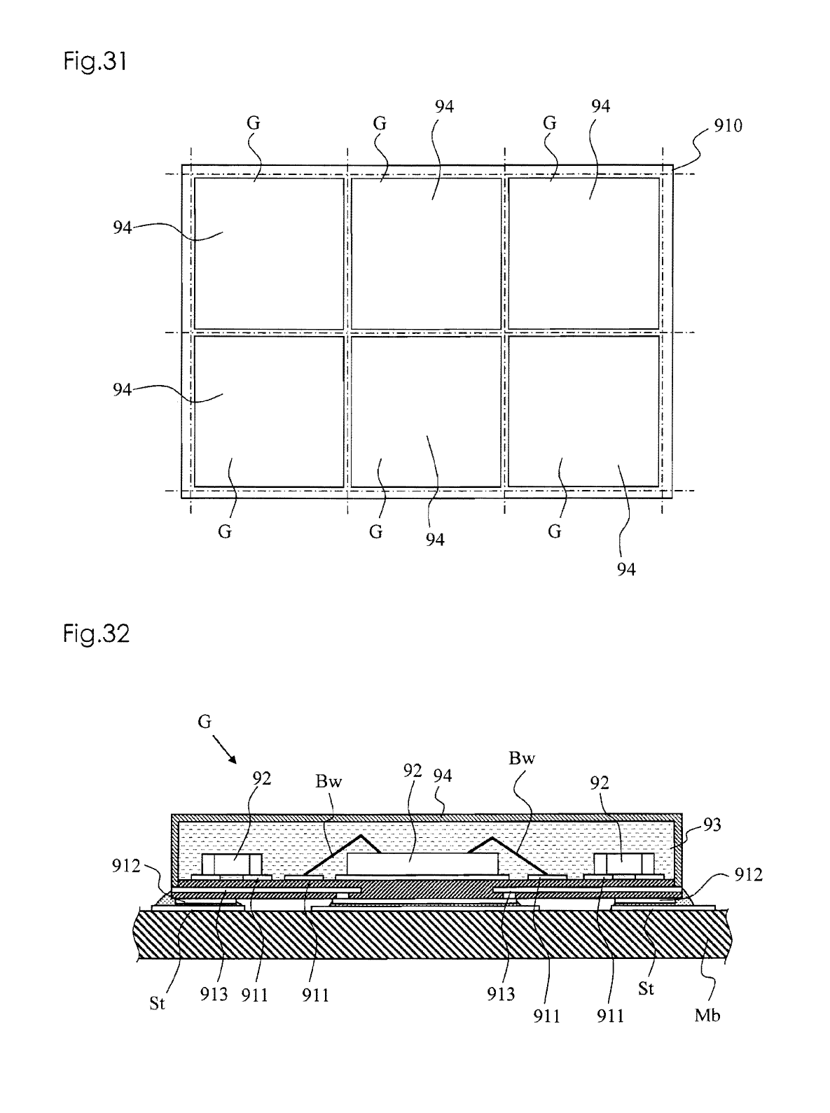

Yet another example of the semiconductor module according to the present invention is described with reference to the drawings. FIG. 23 is a plan view of the yet another example of the semiconductor module according to the present invention, and FIG. 24 is a plan view illustrating the collective substrate after the film forming step of the semiconductor module illustrated in FIG. 23 is finished. A semiconductor module F illustrated in FIG. 23 has the same structure as the semiconductor module B except that an exterior shielding member 4f is different. Substantially similar parts are denoted by the same reference symbols, and detailed description thereof is omitted.

As illustrated in FIG. 23, in plan view of the semiconductor module F, the exterior shielding member 4f is formed smaller in size than the module substrate 1b. The exterior shielding member 4f is smaller in size than the module substrate 1b, but has a size which can reliably perform shielding with respect to the electronic component 2 or against undesirable effects due to the electromagnetical field or static electricity from the electronic component 2.

FIG. 24 is a plan view of the collective substrate in a state after the film forming step is completed. The mounting step, the encapsulating step, and the drilling step in the manufacturing steps for the semiconductor module F are the same as those for the semiconductor module B. That is, the plurality of electronic components 2 are mounted on the upper surface of the collective substrate 100 (see FIG. 4), and the upper surface of the collective substrate 100 is encapsulated together with the electronic components 2 with an insulating resin, to thereby form the encapsulation resin layer 3 (see FIG. 5). After that, the recessed holes Vh are formed at the predetermined position from above the encapsulation resin layer 3 (see FIG. 14).

After the recessed hole Vh is formed in the drilling step, a plating resist Mr is applied to the boundary portions of the module regions 101 on the upper surface of the encapsulation resin layer 3. At the portions at which the plating resist Mr is formed, there are formed the dicing lines DL along which the collective substrate is cut by the dicing blade in the dicing step. On the upper surface of the encapsulation resin layer 3 on which the plating resist Mr is formed, the metal coating film is formed by a plating method (see FIG. 24). The film forming step is performed so that, on the upper surface of the encapsulation resin layer 3, the plating resist Mr is formed on the dicing lines DL, and the metal coating film is formed only at portions excluding the dicing lines DL.

After the metal coating film is formed on the upper surface of the encapsulation resin layer 3, the plating resist Mr is removed. On the dicing lines DL, the metal coating film is not formed. In the above mentioned embodiments, in the dicing step, when the exterior shielding member 4 corresponding to the metal coating film is cut, load to the dicing blade Db is larger compared to the case where the module substrate 1b or the encapsulation resin layer 3 is cut.

Therefore, as illustrated in FIG. 24, the metal coating film is prevented from being formed on the dicing lines DL by using the plating resist Mr so that the dicing blade does not cut the metal coating film. In this manner, wearing of the dicing blade is suppressed. Further, it is possible to reduce the stress to be applied to the encapsulation resin layer 3 or the module substrate 1b when the dicing blade cuts the metal coating film in the dicing step. Note that, in this embodiment, for easy understanding, a region applied with the plating resist is illustrated large. However, actually, it is possible to set the region to be substantially the same as or slightly larger than the width of the dicing blade. It is possible to adopt various forms which prevent the dicing blade from being brought into contact with the metal coating film and include the exterior shielding member 4 in a size capable of reliably performing shielding against undesirable effects due to the electromagnetical field or static electricity.

Note that, in this embodiment, the structure of the semiconductor module F is the same as that of the semiconductor module B, but the present invention is not limited thereto.

Other effects of the sixth embodiment are the same as those in the above-mentioned first to fifth embodiments.

The embodiments of the present invention have been described above. However, the present invention is not limited to what has been described above. The embodiments may be modified in various ways without departing from the spirit of the present invention.

For example, in the respective embodiments described above, there is described an example in which the ceramic multilayer substrate is used as the module substrate (collective substrate), but the present invention is not limited thereto. Substrates other than the ceramic multilayer substrate may be used. For example, a glass epoxy multilayer substrate or a multilayer resin substrate may be used.

Further, in the respective embodiments described above, an epoxy resin is exemplified as the insulating resin forming the encapsulation resin layer, but the present invention is not limited thereto. There may be adopted various resins, which have insulating properties and are excellent in processability (fluidity, curing property, and the like). Further, as a method of forming the encapsulation resin layer, the transfer molding method is adopted, but the present invention is not limited thereto. There may be adopted various methods, which are capable of accurately and reliably form the encapsulation resin layer. Further, the position of the connection portion is not particularly limited as long as the connection portion is provided inside the encapsulation resin layer in plan view.

Further, in the respective embodiments described above, a copper film is used as the metal coating film forming the exterior shielding member, but the present invention is not limited thereto. For example, an aluminium film and the like may be used. Further, instead of a copper film and an aluminium film, there may be adopted various metal coating films which have excellent conductivity and can be easily processed. Further, in the respective embodiments described above, there is adopted a plating method as a method of forming the metal coating film. However, the present invention is not limited thereto. For example, a method of sputtering, vapor deposition, and the like may be used. There may be adopted various methods capable of forming the metal coating film, which is unlikely to peel off, from the upper surface of the encapsulation resin layer.

Further, in the respective embodiments described above, there is described an example in which a WL-CSP type semiconductor device is mounted on the module substrate, but the present invention is not limited thereto, and a semiconductor device other than the WL-CSP type can be mounted. Further, there may be provided a plurality of WL-CSP type semiconductor devices and (or) a plurality of semiconductor devices other than the WL-CSP type. At this time, the semiconductor device and the wiring conductor of the module substrate may be connected to each other by soldering a terminal formed on the undersurface as described above, or by using a bonding wire.

The semiconductor module according to the present invention can be safely mounted onto a small-sized electronic devices such as a mobile phone, a digital camera, and a portable information terminal.

What is claimed is:

1. A semiconductor module, comprising:
a substrate having an electronic component mounted on an upper surface thereof;
an encapsulation resin layer having an insulating property, for encapsulating the upper surface on which the electronic component is mounted;
an exterior shielding member having conductivity, for covering a side of the encapsulation resin layer opposite to the substrate; and
a connection portion, which is provided inside the encapsulation resin layer, for electrically connecting the exterior shielding member and a ground terminal provided to the substrate.

2. A semiconductor module according to claim 1, further comprising a recessed portion, which passes through the exterior shielding member and reaches at least an inner portion of the encapsulation resin layer,
wherein the connection portion comprises an inner peripheral portion, which covers an inner peripheral surface of the recessed portion and a contact portion provided in contact with the ground terminal.

3. A semiconductor module according to claim 2,
wherein the substrate has the ground terminal arranged on an undersurface thereof; and
wherein the recessed portion passes through the encapsulation resin layer, the substrate, and the ground terminal.

4. A semiconductor module according to claim 2,
wherein the recessed portion passes through the encapsulation resin layer, and
wherein the contact portion of the connection portion is formed so as to cover a bottom surface of the recessed portion so that the contact portion is provided in contact with the ground terminal formed on the upper surface of the substrate.

5. A semiconductor module according to claim 2,
wherein the recessed portion is formed above the electronic component, and
wherein the contact portion is provided in contact with a conductor portion of the electronic component, which is connected to the ground terminal.

6. A semiconductor module according to claim 5,
wherein the electronic component comprises a semiconductor device including a through silicon via.

7. A semiconductor module according to claim 2,
wherein the ground terminal is formed on the upper surface of the substrate,
wherein the substrate has a conductive member mounted thereon, the conductive member being connected to the ground terminal and provided upright in a thickness direction of the substrate, and
wherein the contact portion is provided in contact with the conductive member.

8. A semiconductor module according to claim 1,
wherein the exterior shielding member is smaller in planar shape than the substrate.

9. A semiconductor module according to claim 1,
wherein the connection portion comprises a plurality of connection portions.

10. A semiconductor module according to claim 9,
wherein the plurality of connection portions are arranged so as to form a pair at least at diagonal positions of the substrate.
